(19) United States
(12) Patent Application Publication
(10) Pub. No.: US 2017/0351365 A1
(43) Pub. Date: Dec. 7, 2017

(54) DISPLAY DEVICE

(71) Applicant: Japan Display Inc., Tokyo (JP)

(72) Inventors: Tohru SASAKI, Tokyo (JP); Takahiro FUJIOKA, Tokyo (JP)

(21) Appl. No.: 15/592,795

(22) Filed: May 11, 2017

(30) Foreign Application Priority Data
Jun. 6, 2016 (JP) 2016-112484

(51) Int. Cl. G06F 3/041; H01L 27/32; G06F 3/044

(52) U.S. Cl. CPC G06F 3/0412; H01L 27/3262; H01L 27/323; H01L 27/3276; G06F 3/044; G06F 2203/04111; H01L 2227/323

(57) ABSTRACT

Disclosed is a display device which includes: a base film having a display region, a touch region, and a boundary region between the display region and the touch region; an image-display portion provided in the display region; and a touch portion provided in the touch region. The image-display portion has a transistor including a gate electrode and a source/drain electrode. The touch portion has a plurality of electrodes electrically connected to each other with a connection electrode. The base film is folded in the boundary region so that a back surface of the touch portion opposes the image-display portion with the touch portion sandwiched therebetween. The image-display portion and the touch portion are sandwiched by the base film. The back surface of the touch portion is one of two surfaces of the touch portion opposing each other, which is closer to the base film.

### CROSS REFERENCE TO RELATED APPLICATIONS

This application is based on and claims the benefit of priority from the prior Japanese Patent Application No. 2016-112484, filed on Jun. 6, 2016, the entire contents of which are incorporated herein by reference.

### FIELD

An embodiment of the present invention relates to a display device such as an organic EL display device and a manufacturing method thereof. For example, an embodiment relates to a display device on which a touch panel is mounted and a manufacturing method thereof.

### BACKGROUND

A touch panel has been known as an interface for a user to input information. Arrangement of a touch panel over a screen of a display device allows a user to operate input buttons, icons, and the like displayed on a screen, by which information can be readily input to a display device. For instance, Japanese patent application publications No. 2001-154178 and No. 2001-117719 disclose a stacked-type display device in which a touch panel is installed over a liquid crystal display device.

### SUMMARY

An embodiment of the present invention is a display device which includes: a base film having a display region, a touch region, and a boundary region between the display region and the touch region; an image-display portion provided in the display region; and a touch portion provided in the touch region. The image-display portion has a transistor including a gate electrode and a source/drain electrode. The touch portion has a plurality of electrodes electrically connected to each other with a connection electrode. The connection electrode exists in the same layer as one of the gate electrode and the source/drain electrode. The base film is folded in the boundary region so that a back surface of the touch portion opposes the image-display portion with the touch portion sandwiched therebetween. The image-display portion and the touch portion are sandwiched by the base film. The back surface of the touch portion is one of two surfaces of the touch portion opposing each other, which is closer to the base film.

An embodiment of the present invention is a display device which includes: a base film having a display region, a touch region, and a boundary region between the display region and the touch region; an image-display portion over the display region; and a touch portion over the touch region. The baes film is folded in the boundary region so that a front surface of the touch portion overlaps with the image-display portion with the touch portion sandwiched therebetween. The boundary region protrudes from a region in which the image-display portion and the touch portion overlap with each other, and the base film in a protruding portion has a three-folded structure. The front surface of the touch portion is one of two surfaces of the touch portion opposing each other, which is farther from the base film.

An embodiment of the present invention is a display device which includes: a base film having a display region, a touch region, and a boundary region between the display region and the touch region; an image-display portion over the display region; and a touch portion over the touch region. The baes film is folded in the boundary region so that a front surface of the touch portion overlaps with the image-display portion with the touch portion sandwiched therebetween. The base film in the boundary region has a three-folded structure and is sandwiched between the display region and the touch region. The front surface of the touch portion is one of two surfaces of the touch portion opposing each other, which is farther from the base film.

An embodiment of the present invention is a manufacturing method of a display device. The manufacturing method includes; forming a display panel and a touch panel over a base film; and folding the base film in a region sandwiched between the display panel and the touch panel so that a touch region is located over and overlaps with a display region and the base film extends from under the display panel to over the touch panel.

An embodiment of the present invention is a manufacturing method of a display device. The manufacturing method includes: forming a display panel and a touch panel over a base film; forming a slit in the base film in a region between the display panel and the touch panel; and three-folding the region so that the touch panel is located and overlaps with the display panel and the base film under the touch panel is sandwiched between the display panel and the touch panel.

### BRIEF DESCRIPTION OF DRAWINGS

FIG. 1A and FIG. 1C are schematic top views, and FIG. 1B is a schematic cross-sectional view of a display device according to an embodiment of the present invention;

FIG. 2 is a schematic developed view of a display device according to an embodiment of the present invention;

FIG. 3 is a schematic top view of a touch portion of a display device according to an embodiment of the present invention;

FIG. 4 is a schematic top view of an image-display portion of a display device according to an embodiment of the present invention;

FIG. 5 is a schematic cross-sectional view of a display device according to an embodiment of the present invention;

FIG. 6A and FIG. 6B are schematic cross-sectional views showing a manufacturing method of a display device according to an embodiment of the present invention;

FIG. 7A and FIG. 7B are schematic cross-sectional views showing a manufacturing method of a display device according to an embodiment of the present invention;

FIG.8A and FIG. 8B are schematic cross-sectional views showing a manufacturing method of a display device according to an embodiment of the present invention;

FIG.9A and FIG. 9B are schematic cross-sectional views showing a manufacturing method of a display device according to an embodiment of the present invention;

FIG. 10A and FIG. 10B are schematic cross-sectional views showing a manufacturing method of a display device according to an embodiment of the present invention;

FIG. 11A and FIG. 11B are schematic cross-sectional views showing a manufacturing method of a display device according to an embodiment of the present invention;

FIG. 12A and FIG. 12B are schematic cross-sectional views showing a manufacturing method of a display device according to an embodiment of the present invention;

FIG. 13A and FIG. 13B are schematic cross-sectional views showing a manufacturing method of a display device according to an embodiment of the present invention;

FIG. 14 is a schematic cross-sectional view showing a manufacturing method of a display device according to an embodiment of the present invention;

FIG. 15A and FIG. 15B are schematic cross-sectional views of a display device according to an embodiment of the present invention;

FIG. 16 is a schematic cross-sectional view of a display device according to an embodiment of the present invention;

FIG. 17 is a schematic cross-sectional view of a display device according to an embodiment of the present invention;

FIG. 18 is a schematic top view of a display device according to an embodiment of the present invention;

FIG. 19 is a schematic developed view of a display device according to an embodiment of the present invention;

FIG. 20 is a schematic top view of a display device according to an embodiment of the present invention;

FIG. 21 is a schematic developed view of a display device according to an embodiment of the present invention;

FIG. 22 is a schematic top view of a display device according to an embodiment of the present invention;

FIG. 23 is a schematic developed view of a display device according to an embodiment of the present invention;

FIG. 24 is a schematic top view of a display device according to an embodiment of the present invention;

FIG. 25A to FIG. 25C are schematic cross-sectional views of a display device according to an embodiment of the present invention;

FIG. 26 is a schematic developed view of a display device according to an embodiment of the present invention;

FIG. 27 is a schematic developed view of a display device according to an embodiment of the present invention;

FIG. 28 is a schematic top view of a display device according to an embodiment of the present invention;

FIG. 29A to FIG. 29C are schematic cross-sectional views of a display device according to an embodiment of the present invention;

FIG. 30 is a schematic developed view of a display device according to an embodiment of the present invention;

FIG. 31 is a schematic developed view of a display device according to an embodiment of the present invention;

FIG. 32 is a schematic top view of a display device according to an embodiment of the present invention;

FIG. 33A to FIG. 33C are schematic cross-sectional views of a display device according to an embodiment of the present invention;

FIG. 34 is a schematic developed view of a display device according to an embodiment of the present invention;

FIG. 35 is a schematic developed view of a display device according to an embodiment of the present invention;

FIG. 36 is a schematic top view of a display device according to an embodiment of the present invention;

FIG. 37A and FIG. 37B are respectively a schematic cross-sectional view and side view of a display device according to an embodiment of the present invention;

FIG. 38 is a schematic top view of a display device according to an embodiment of the present invention;

FIG. 39 is a schematic developed view of a display device according to an embodiment of the present invention;

FIG. 40 is a schematic top view of a display device according to an embodiment of the present invention;

FIG. 41 is a schematic developed view of a display device according to an embodiment of the present invention;

FIG. 42 is a schematic top view of a display device according to an embodiment of the present invention;

FIG. 43 is a schematic developed view of a display device according to an embodiment of the present invention;

FIG. 44A and FIG. 44B are schematic top views of a display device according to an embodiment of the present invention;

FIG. 45A to FIG. 45C are schematic cross-sectional views of a display device according to an embodiment of the present invention;

FIG. 46 is a schematic developed view of a display device according to an embodiment of the present invention;

FIG. 47A and FIG. 47B are schematic top views of a display device according to an embodiment of the present invention;

FIG. 48 is a schematic developed view of a display device according to an embodiment of the present invention;

FIG. 49 is a top view showing a manufacturing method of a display device according to an embodiment of the present invention; and

FIG. 50 is a top view showing a manufacturing method of a display device according to an embodiment of the present invention.

### DESCRIPTION OF EMBODIMENTS

Hereinafter, the embodiments of the present invention are explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate.

In the present invention, when a plurality of films is formed by processing one film, the plurality of films may have functions or rules different from each other. However, the plurality of films originates from a film which is formed as the same layer in the same process. Therefore, the plurality of films is defined as films existing in the same layer.

In the specification and the scope of the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

### First Embodiment

### 1. Outline Structure

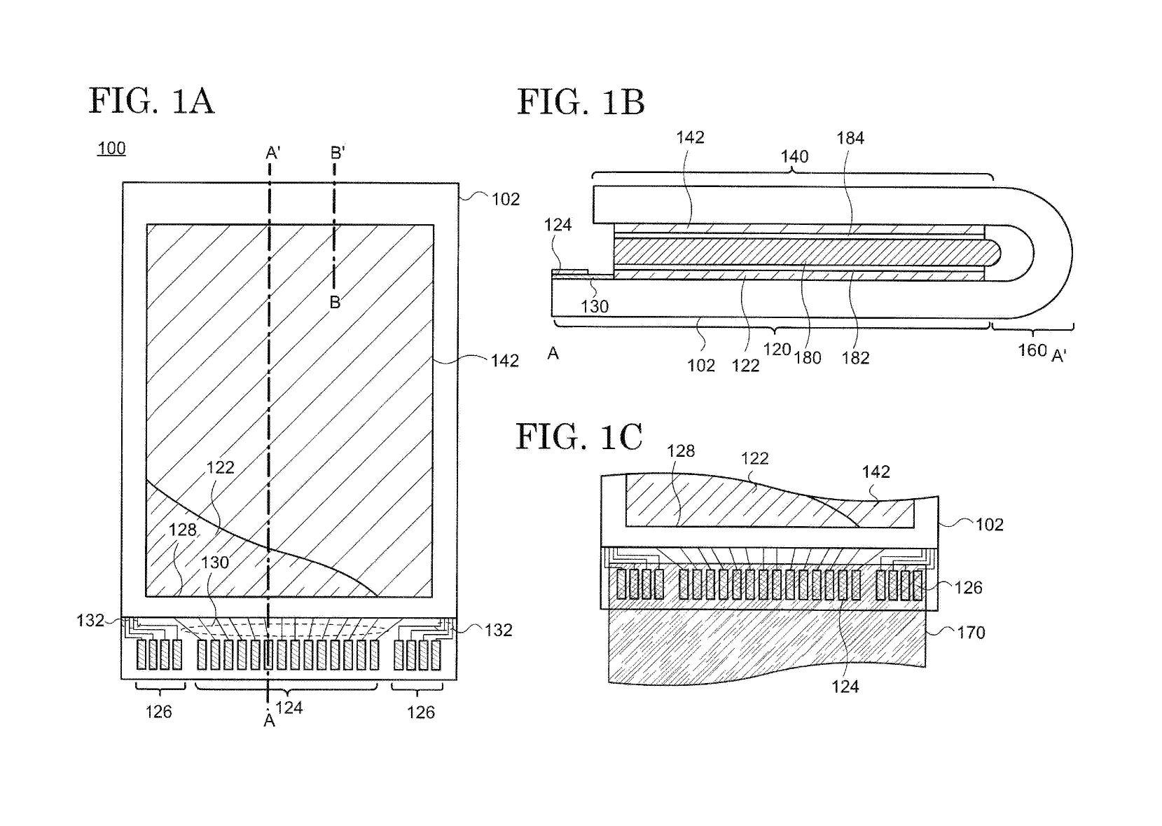

In the present embodiment, a structure of a display device 100 of an embodiment of the present invention is explained by using FIG. 1A to FIG. 5.

Schematic top views of the display device 100 of the present embodiment are shown in FIG. 1A and FIG. 1C, and a schematic cross-sectional view along a chain line A-A′ of FIG. 1A is shown in FIG. 1B. As shown in FIG. 1B, the display device 100 has a base film 102, and the base film 102 possesses a display region 120, a touch region 140, and a boundary region 160 between the display region 120 and the touch region 140. The touch region 140 is located over and overlaps with the display region 120. The boundary region 160 connects the display region 120 to the touch region 140. The base film 102 is a plate or a film with flexibility and has a light-transmitting property to visible light.

An image-display portion 122 is provided over the base film 102 in the display region 120. As described below, a plurality of pixels is disposed in the image-display portion 122. A driver circuit and the like for driving the pixels can be provided to the display region 120, and an image is reproduced on the image-display portion 122 by the plurality of pixels.

A touch portion 142 is provided under the base film 102 in the touch region 140. The touch portion 142 is the same or substantially the same in size and shape as the image-display portion 122 and overlaps with the image-display portion 122 (FIG. 1A). As described below, the touch portion 142 has a function to sense a touch by contacting (hereinafter, referred to as touch) with an object such as a finger and a palm through the base film 102 and serves as an interface for inputting information by a user. For example, an electrostatic capacity type, a resistive film type, an electromagnetic induction type can be employed in the touch portion 142. As shown in FIG. 1A, a user recognizes the image-display portion 122 through the touch portion 142.

As described above, the base film 102 in the display region 120 and the base film 102 in the touch region 140 are connected to each other in the boundary region 160. In other words, the base film 102 in the boundary region 160, the base film 102 in the display region 120, and the base film 102 in the touch region 140 are integrated, and the base film 102 in the display region 120 extends from under the image-display portion 122 to over the touch portion 142 through the boundary region 160. Therefore, the base films 102 of the display region 120, the boundary region 160, and the touch region 140 have a continuous structure, and the image-display portion 122 and the touch portion 142 are enclosed by the base film 102.

The display region 120 further possesses a plurality of first terminals 124 and a plurality of second terminals 126 over the base film 102. Each of the plurality of first terminals 124 and the plurality of second terminals 126 is arranged so that at least part of them does not overlap with the base film 102 of the touch region 140. That is, each of the first terminals 124 and the plurality of second terminals 126 is at least partially exposed from the base film 102 of the touch region 140.

The first terminals 124 and the second terminals 126 are arranged at a vicinity of a side (first side) 128 of the image-display portion 122 substantially parallel to the first side 128. The first terminals 124 are electrically connected to the image-display portion 122 through wirings 130 provided over the base film 102. On the other hand, the second terminals 126 are electrically connected to the touch portion 142 through wirings 132 formed over the base film 102 in the display region 120. In FIG. 1A, the plurality of second terminals 126 is illustrated so as to sandwich the plurality of first terminals 124. However, the second terminals 126 may be collectively provided in one specified place.

As shown in FIG. 1C, the first terminals 124 and the second terminals 126 are connected to a connector 170 such as a flexible printed circuit substrate (FPC), and signals are input to the image-display portion 122 and the touch portion 142 from an external circuit through the connector 170, the first terminals 124, and the second terminals 126. For example, the first terminals 124 are supplied with image signals and a power source, and the second terminals 126 are supplied with detection signals for detecting a touch, and the like.

As shown in FIG. 1A to FIG. 1C, the first terminals 124 and the second terminals 126 each are provided over the base film 102 in the display region 120 and are arranged at the vicinity of the first side 128 so as to be parallel to the first side 128. Hence, the first terminals 124 and the second terminals 126 can be connected to a single connector 170. Hence, compared with a case where the first terminals 124 and the second terminals 126 are connected to different connectors, the number of the connectors can be reduced by half, thereby decreasing manufacturing cost and simplifying a manufacturing process.

The display region 120 and the touch region 140 may be adhered to each other. For example, as shown in FIG. 1 B, the display region 120 and the touch region 140 may be adhered through adhesion layers 182 and 184. In this case, a transparent substrate 180 may be provided as an optional structure between the display region 120 and the touch region 140 to adjust a thickness of the display device 100. It is preferred that the transparent substrate 180 have a light-transmitting property to visible light. The transparent substrate 180 may have flexibility. Note that an edge of the transparent substrate 180 close to the boundary region 160 may be subjected to chamfering so as to have a round shape in order to prevent the base film 102 in the boundary region 160 from being damaged by the transparent substrate 180.

### 2. Developed Structure

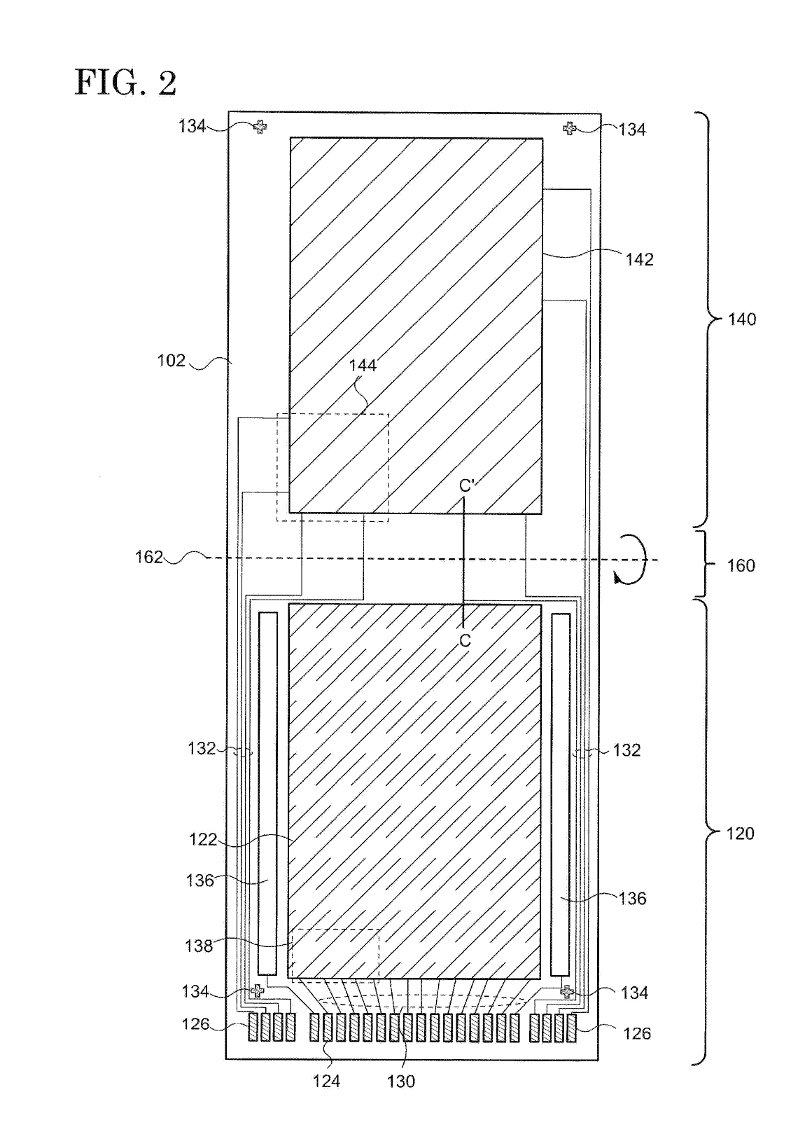

A developed state of the display device 100 is shown in FIG. 2 to explain the structure of the display device 100 in more detail. FIG. 2 corresponds to a state where the transparent substrate 180 and the adhesion layers 182 and 184 are removed from the display device 100 shown in FIG. 1 B and the boundary region 160 is flattened.

As shown in FIG. 2, the base film 102 has the display region 120, the touch region 140, and the boundary region 160 between the display region 120 and the touch region 140. The touch region 140 is provided with the touch portion 142, while the image-display portion 122 is provided to the display region 120. In the display device 100 shown in FIG. 2, driver circuits 136 are disposed in the display region 120 so as to sandwich the image-display portion 122. However, the driver circuits 136 are an optional structure, and a driver circuit formed on a different substrate and the like may be additionally provided to the display device 100. In this case, the driver circuit can be mounted over the wirings 130, connector 170, or the like, for example.

The wirings 132 electrically connect the second terminals 126 to the touch portion 142, pass through a region (frame) beside the image-display portion 122, and extend to the touch region 140 from the display region 120 through the boundary region 160. The wirings 130 electrically connect the first terminals 124 to the image-display portion 122. Although not shown, the wirings 132 may be arranged in the boundary region 160 so as to extend in a direction inclined from each of the sides of the image-display portion 122 and the touch portion 142.

Alignment markers 134 may be provided over the base film 102. The boundary region 160 is folded along an axis 162 so that the alignment markers 134 overlap with each other and the display region 120 and the touch region 140 are adhered to each other, by which the display device 100 shown in FIG. 1A to FIG. 1C can be obtained.

### 3. Touch Portion

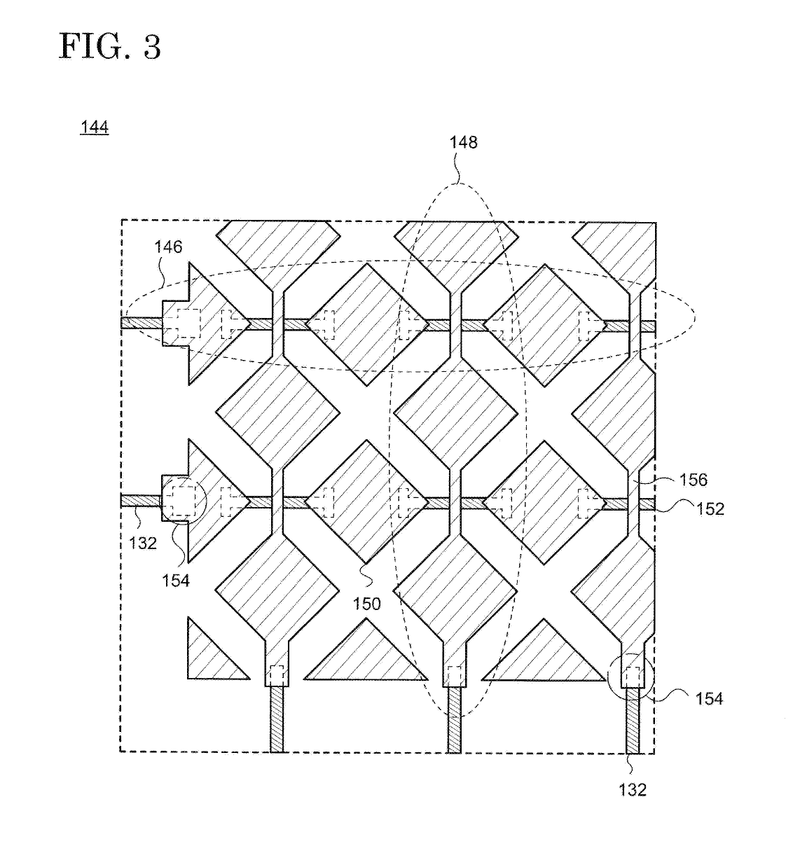

An enlarged figure of a partial region 144 of the touch portion 142 is schematically shown in FIG. 3. The touch portion 142 is able to detect a touch with a variety of modes. Here, explanation is given using a touch portion of an electrostatic capacity type as an example.

The touch portion 142 has a structure in which a plurality of wirings is arranged in a lattice form. Specifically, the touch portion 142 has a plurality of wirings (Tx wirings 146) extending in a first direction (e.g., a direction parallel to the first side 128. See FIG. 1A) and a plurality of wirings (Rx wirings 148) perpendicularly intersecting with the Tx wirings 146. Each wiring includes a plurality of substantially square electrodes 150. For example, in each of the Tx wirings 146, the plurality of electrodes 150 is arranged in the first direction, and the adjacent electrodes 150 are electrically connected with a Tx bridge electrode (connection electrode) 152. In FIG. 3, an example is shown where the electrodes 150 are formed over the Tx bridge electrodes 152. The wirings 132 are connected to terminal electrodes of the Tx wirings 146 (the left edge electrodes in FIG. 3) through the wiring connection ports 154. On the other hand, the Rx wirings 148 have a structure in which the plurality of electrodes 150 and Rx bridge portions 156 connecting the electrodes 150 with each other are integrally formed. The wirings 132 are connected to terminal electrodes (lower edge electrodes in FIG. 3) of the Rx wirings 148 through the wiring connection ports 154.

Each electrode 150 and Rx bridge portion 156 are formed with a conductor transmitting visible light, such as a conductive oxide, for example. On the other hand, it is not necessary for the Tx bridge electrodes 152 to transmit visible light, and the Tx bridge electrodes 152 may be formed with a metal which does not transmit visible light, in addition to a conductive oxide transmitting visible light.

### 4. Image-Display Portion

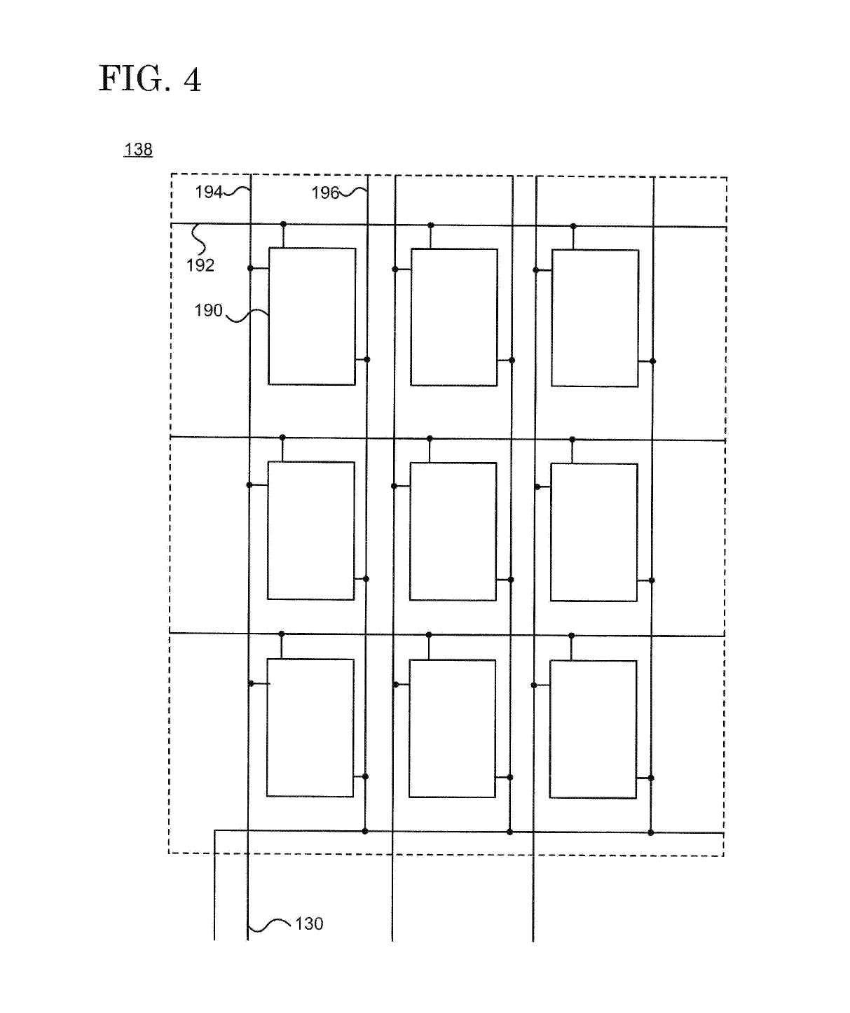

An enlarged figure of a region 138 which is a part of the image-display portion 122 is schematically shown in FIG. 4. The image-display portion 122 possesses a plurality of pixels 190. Display elements such as a light-emitting element or a liquid crystal element can be provided in the plurality of pixels 190. For example, three adjacent pixels 190 are configured to give red, green, or blue color, by which full-color display can be accomplished. There is also no limitation to an arrangement of the pixels 190, and a stripe arrangement, a delta arrangement, a Pentile arrangement, and the like may be employed. Compared with the stripe arrangement and the delta arrangement, the Pentile arrangement is effective at increasing apparent resolution with a smaller number of pixels. For example, a part of RGB pixels is arranged in a matrix form with vertical and lateral directions, while the other part of the RGB pixels are arranged alternatively with the part of the pixels in a diagonal direction. The Pentile arrangement is characterized in that the number of sub-pixels is different between RGB.

One or a plurality of transistors are provided in each pixel 190, and a plurality of signal lines 192, 194, and 196 supplying signals to the respective transistors are formed in a lattice form. For example, the signal lines 194, 192, and 196 can respectively supply an image signal, a scanning signal, and a high-potential power-source voltage to each pixel 190. Although not shown, the image-display portion 122 may have a wiring other than the aforementioned wirings. These wirings are connected to the first terminals 124 through the driver circuits 136 or the wirings 130.

### 5. Cross-Sectional Structure

5-1. Display Region

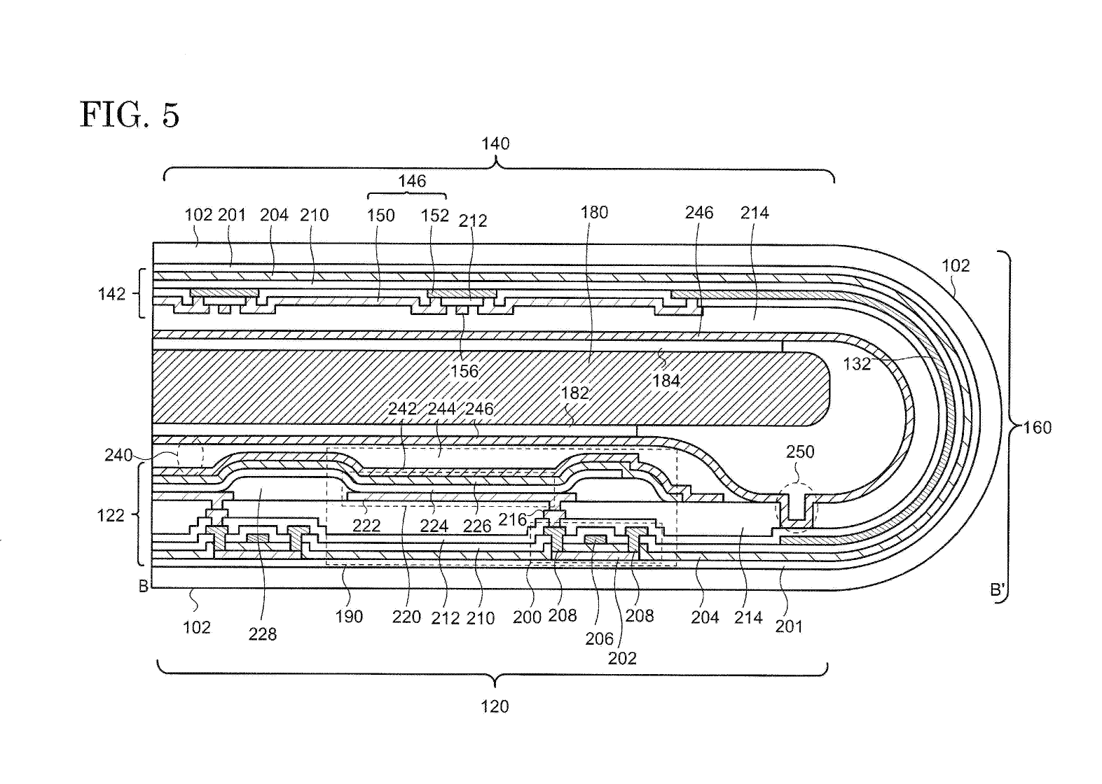

A cross-sectional structure of the display device 100 is explained in detail by using FIG. 5. FIG. 5 is a schematic view of a cross-section along a chain line B-B′ of FIG. 1A.

In the display region 120, the image-display portion 122 is formed over the base film 102, and each pixel 190 of the image-display portion 122 may include a transistor 200 and a light-emitting element 220 connected to the transistor 200. An example is shown in FIG. 5 in which one transistor is formed in each pixel 190. However, each pixel 190 may possess a plurality of transistors. Moreover, each pixel 190 may contain semiconductor elements other than a transistor, such as a capacitor element. An undercoat 201 may be disposed as an optional structure between the base film 102 and the transistor 200.

The transistor 200 has a semiconductor film 202, a gate insulating film 204, a gate electrode 206, and a pair of source/drain electrodes 208. A first interlayer film 210 may be arranged over the gate electrode 206, and the source/drain electrodes 208 are connected to the semiconductor film 202 through opening portions provided in the gate insulating film 204 and the first interlayer film 210.

FIG. 5 is illustrated so that the transistor 200 has a top-gate top-contact type structure. However, the structure of the transistor 200 is not limited, and the transistor 200 may possess a bottom-gate type or a top-gate type. There is also no limitation to a vertical relationship between the semiconductor film 202 and the source/drain electrode 208. Additionally, a so-called multi-gate type structure in which a plurality of gate electrodes 206 are provided may be employed in the transistor 200.

A second interlayer film 212 may be formed over the transistor 200, and a leveling film 214 may be formed thereover to absorb depressions and projections caused by the transistor 200 and the like and give a flat surface.

The light-emitting element 220 has a first electrode 222, a second electrode 226, and an EL layer 224 provided between the first electrode 222 and the second electrode 226. The first electrode 222 is electrically connected to one of the source/drain electrodes 208 of the transistor 200 through a connection electrode 216. The first electrode 222 may include a conductive oxide with a light-transmitting property, a metal, or the like. When light obtained from the light-emitting element is extracted through the touch region 140, a metal such as aluminum or silver or an alloy thereof can be used for the first electrode 222. In this case, a stacked structure of the aforementioned metal or alloy with a conductive oxide having a light-transmitting property, e.g., a stacked structure in which a metal is sandwiched by a conductive oxide (indium-tin oxide (ITO)/silver/ITO, etc.), may be employed.

A partition wall 228 covering an edge portion of the first electrode 222 may be formed in the image-display portion 122. The partition wall 228 is also called a bank (rib). The partition wall 228 has an opening portion to expose a part of the first electrode 222, and an edge of the opening portion is preferred to have a tapered shape. A steep edge of the opening portion readily causes a coverage defect of the EL layer 224 and the second electrode 226.

The EL layer 224 is formed so as to cover the first electrode 222 and the partition wall 228. Note that, in the present specification, the EL layer 224 means all of the layers sandwiched by a pair of electrodes (here, the first electrode 222 and the second electrode 226).

For the second electrode 226, it is possible to use a film containing a conductive oxide with a light-transmitting property, such as ITO and indium-zinc oxide (IZO), or a metal film which is formed at a thickness exhibiting a light-transmitting property and which includes silver, magnesium, aluminum, or the like. This structure allows the emission from the EL layer 224 to be extracted through the touch region 140.

The image-display portion 122 may further possess a passivation film 240 over the light-emitting element 220. The passivation film 240 has a function to prevent moisture from entering the light-emitting element 220 from outside and is preferred to have a high gas-barrier property. The passivation film 240 shown in FIG. 5 has a three-layer structure and includes a first layer 242 and a third layer 246 containing an inorganic material and a second layer 244 interposed therebetween and containing an organic resin.

Note that the leveling film 214 may have, as an optional structure, an opening portion 250 reaching the second interlayer film 212 between the pixel 190 closest to the boundary region 160 and the boundary region 160. Furthermore, the passivation film 240 may be formed so that the second interlayer film 212 is in contact with the third layer 246 in the opening portion 250. Introduction of such a structure prevents impurities from being diffused in the leveling film 214 and entering the light-emitting element 220 from the boundary region 160.
5-2. Touch Region

The touch region 140 has the undercoat 201 extending from the display region 120 through the boundary region 160, the gate insulating film 204, and the first interlayer film 210 and possesses the touch portion 142 thereunder. As described above, the touch portion 142 has the Tx wirings 146 including the electrodes 150 and the Tx bridge electrodes 152, and the Rx wirings 148 including the electrodes 150 and the Rx bridge portions 156. As described below, the Tx bridge electrodes 152 can be simultaneously formed with the source/drain electrodes 208 or the gate electrode 206 of the transistor 200. That is, the Tx bridge electrodes 152 are able to exist in the same layer as the source/drain electrodes 208 or the gate electrode 206 of the transistor 200. Furthermore, the electrodes 150 and the Rx bridge portions 156 can be formed simultaneously with the connection electrode 216, and therefore, they can exist in the same layer.

The second interlayer film 212 extending to the touch region 140 from the display region 120 through the boundary region 160 is provided between the Tx wirings 146 and the Rx wirings 148, and a capacitor is formed by the Tx wirings 146, the Rx wirings 148, and the second interlayer film 212 which is an insulating film. A contact of a finger or a palm with the touch region 140 through the base film 102 causes capacitive coupling and changes a capacitance at the touched positon, by which a touched position can be sensed.

The leveling film 214 and the third layer 246 of the passivation film 240 extending from the image-display portion 122 through the boundary region 160 are provided under the touch portion 142.
5-3. Boundary Region

The base film 102 can be folded in the boundary region 160. In the boundary region 160, the undercoat 201, the gate insulating film 204, the first interlayer film 210, the second interlayer film 212, the leveling film 214, and the third layer 246 extending from the display region 120 are provided to the base film 102. These films further extend to the touch region 140. In the boundary region 160, the wirings 132 which exist in the same layer as the source/drain electrodes 208 or the gate electrode 206 are disposed between the first interlayer film 210 and the second interlayer film 212. That is, the wirings 132 extend from the display region 120 to the touch region 140 through the boundary region 160.

It is not always necessary that all of the undercoat 201, the gate insulating film 204, the first interlayer film 210, the second interlayer film 212, the leveling film 214, and the third layer 246 are included in the boundary region 160. It is preferred that at least one of the second interlayer film 212, the leveling film 214, and the third layer 246 be formed over the wirings 132 in order to avoid deterioration of the wirings 132.

The display device 100 has the transparent substrate 180 as an optional structure, and the transparent substrate 180 overlaps with the display region 120 and the touch region 140 and is interposed therebetween. The transparent substrate 180 is adhered to the image-display portion 122 and the touch portion 142 with the adhesion layers 182 and 184, respectively. The transparent substrate 180 may be flexible or has low flexibility similar to a glass substrate. The use of the transparent substrate 180 with low flexibility enables the shape of the display device 100 to be fixed.

Although described in detail in the Second Embodiment, each of the layers constructing the boundary region 160 and the touch region 140 is common to the display region 120. Hence, the image-display portion 122 and the touch portion 142 can be simultaneously formed over one base film 102. Therefore, it is not necessary to independently manufacture the image-display portion 122 and the touch portion 142. Additionally, as shown in FIG. 1A and FIG. 1C, signals can be supplied to the image-display portion 122 and the touch portion 142 from an external circuit by using a single connector for the first electrodes 124 and the second electrodes 126. Thus, it is not necessary to separately connect the connectors to the first electrodes 124 and the second electrodes 126. As a result, the structure of the display device 100 and the manufacturing process thereof can be simplified, and the display device 100 equipped with the touch portion 142 can be manufactured at low cost. Moreover, the use of the transparent substrate 180 with flexibility allows production of the flexible display device 100 installed with the touch portion 142.

### Second Embodiment

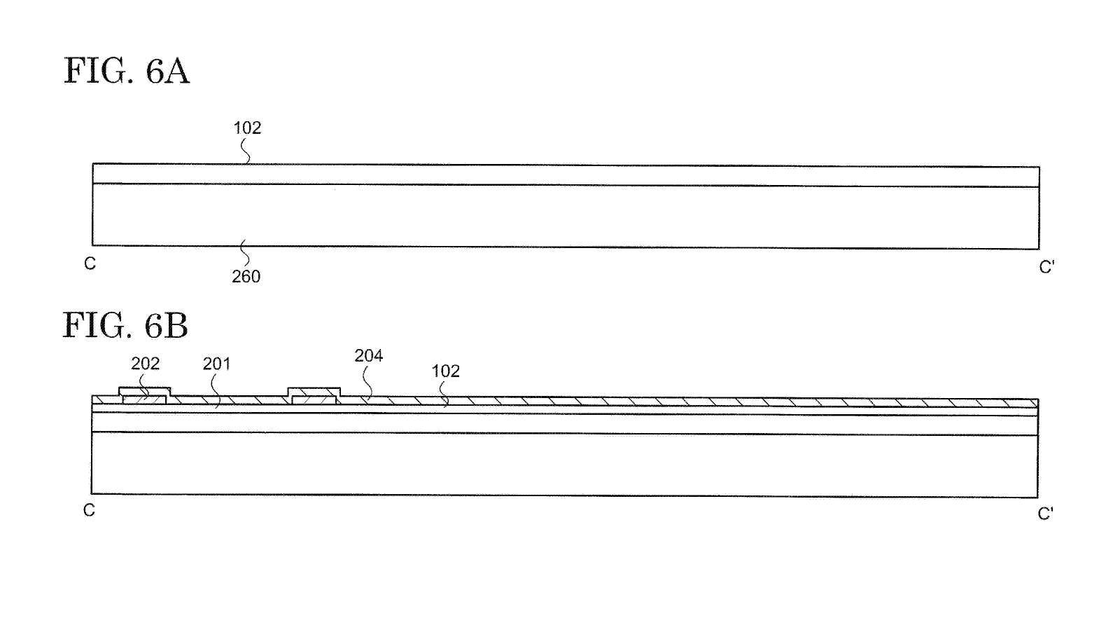

In the present embodiment, a manufacturing method of the display device 100 described in the First Embodiment is explained by using FIG. 5 to FIG. 14. The contents which are the same as those described in the First Embodiment may be omitted. Note that FIG. 6A to FIG. 14 are schematic cross-sectional views along a chain line C-C′ in FIG. 2.

As shown in FIG. 6A, the base film 102 is first formed over a supporting substrate 260. The supporting substrate 260 has a function to support the semiconductor elements included in the image-display portion 122, such as the transistor 200, and the touch portion 142 of the touch region 140. Thus, it is possible to use a material which has heat resistance to the process temperature of the various elements formed thereover and chemical stability to the chemicals used in the process. Specifically, the supporting substrate 260 may include glass, quartz, plastics, a metal, ceramics, and the like.

The base film 102 is an insulating film with flexibility and may contain a material selected from polymer materials exemplified by a polyimide, a polyamide, a polyester, and a polycarbonate. The base film 102 can be prepared by applying a wet-type film-formation method such as a printing method, an ink-jet method, a spin-coating method, and a dip-coating method or a lamination method.

Next, as shown in FIG. 6B, the undercoat 201 is formed over the base film 102. The undercoat 201 is a film functioning to prevent diffusion of impurities from the supporting substrate 206 and the base film 102 to the transistor 200 and the like and may contain an inorganic insulator such as silicon nitride, silicon oxide, silicon nitride oxide, and silicon oxynitride. The undercoat 201 can be formed with a chemical vapor deposition method (CVD method), a sputtering method, a lamination method, and the like so as to have a single-layer or stacked-layer structure. Note that, when an impurity concentration of the base film 102 is low, the undercoat 201 may not be formed or be formed to only partly cover the base film 102.

Next, the semiconductor film 202 is formed. The semiconductor film 202 may contain a Group 14 element such as silicon. Alternatively, the semiconductor film 202 may include an oxide semiconductor. As an oxide semiconductor, Group 13 elements such as indium and gallium are represented, and a mixed oxide of indium and gallium (IGO) is exemplified. When an oxide semiconductor is used, the semiconductor film 202 may further contain a Group 12 element, and a mixed oxide including indium, gallium, and zinc (IGZO) is represented as an example. Crystallinity of the semiconductor film 202 is not limited, and the semiconductor film 202 may be single crystalline, polycrystalline, microcrystalline, or amorphous.

When the semiconductor film 202 includes silicon, the semiconductor film 202 may be formed with a CVD method by using a silane gas and the like as a raw material. Crystallization may be conducted by performing a heat treatment or applying light such as a laser on the obtained amorphous silicon. When the semiconductor film 202 includes an oxide semiconductor, the semiconductor film 202 can be formed by utilizing a sputtering method.

Next, the gate insulating film 204 is formed so as to cover the semiconductor film 202. The gate insulating film 204 may have a single-layer or stacked-layer structure and may be formed with a method similar to that of the undercoat 201.

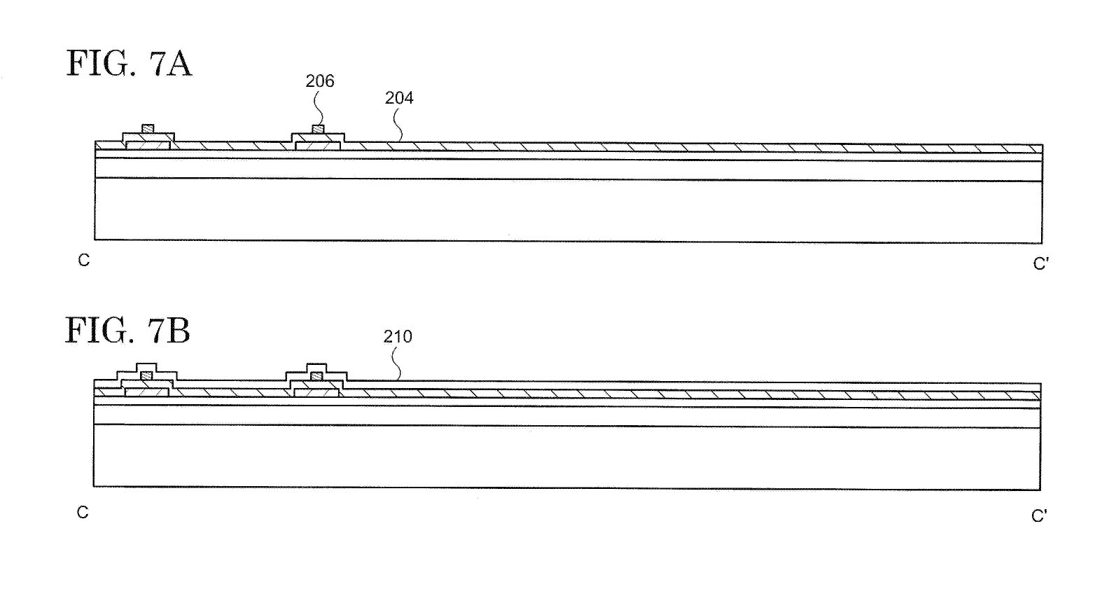

Next, the gate electrode 206 is formed over the gate insulating film 204 by applying a sputtering method or a CVD method (FIG. 7A). The gate electrode 206 can be formed with a metal such as titanium, aluminum, copper, molybdenum, tungsten, and tantalum or an alloy thereof so as to have a single-layer or stacked-layer structure. For example, a structure may be employed in which a metal with a high conductivity, such as aluminum and copper, is sandwiched by a metal with a relatively high melting point, such as titanium, tungsten, and molybdenum.

Next, the first interlayer film 210 is formed over the gate electrode 206 (FIG. 7B). The first interlayer film 210 may have a single-layer or a stacked-layer structure and can be formed with a method similar to that of the undercoat 201.

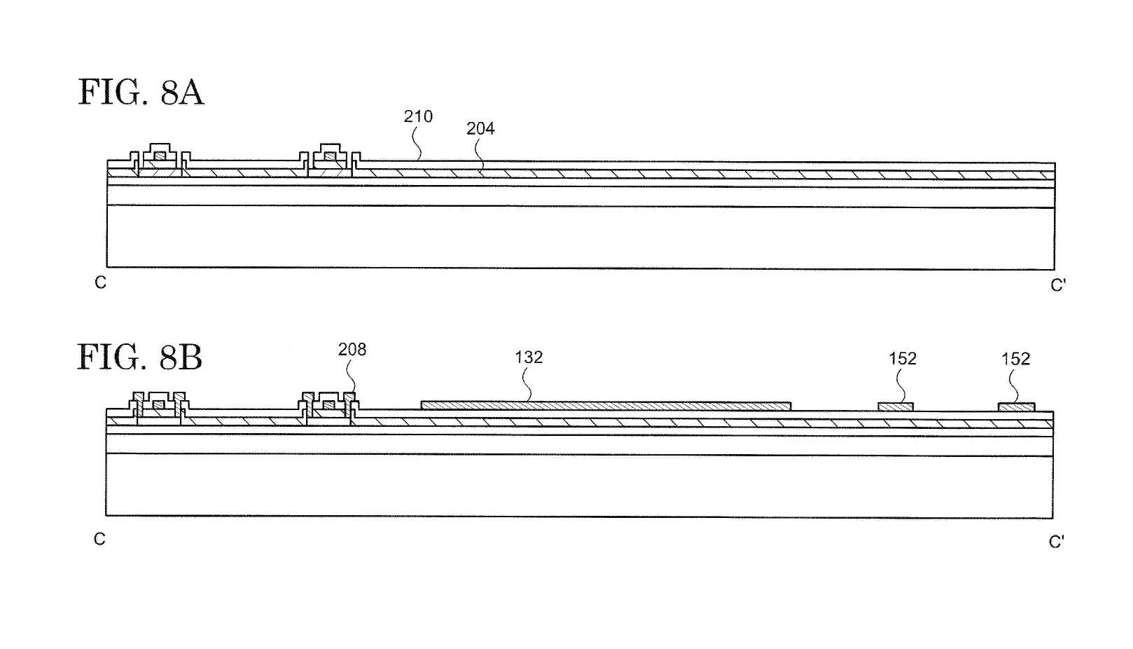

Next, etching is carried out on the first interlayer film 210 and the gate insulating film 204 to form the opening portions reaching the semiconductor film 202 (FIG. 8A). The opening portions may be formed by performing plasma etching in a gas including a fluorine-containing hydrocarbon, for example.

Next, a metal film is formed to cover the opening portions and is processed with etching to form the wirings 132 and the Tx bridge electrodes 152 in addition to the source/drain electrodes 208 (FIG. 8B). Therefore, in the display device 100, the source/drain electrodes 208, the wirings 132, and the Tx bridge electrodes 152 exist in the same layer. The metal film may possess a similar structure as the gate electrode 206 and may be formed with a similar method as that of the gate electrode 206. Although not shown, the wirings 132 and the Tx bridge electrodes 152 may be prepared simultaneously when the gate electrode 206 is formed.

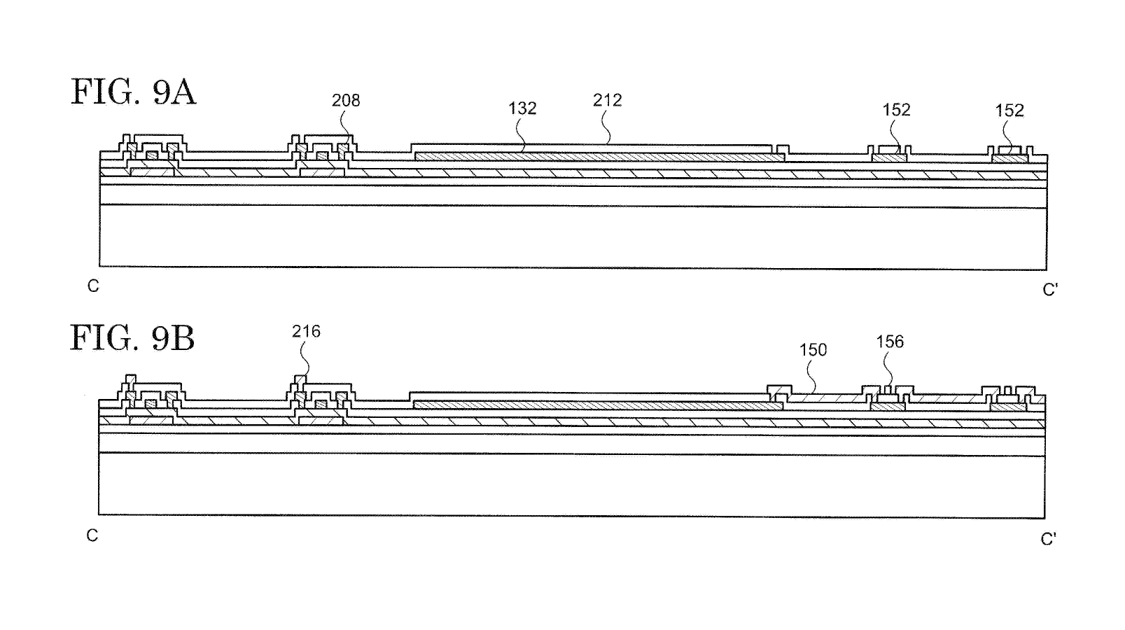

Next, as shown in FIG. 9A, the second interlayer film 212 is formed over the source/drain electrodes 208, the wirings 132, and the Tx bridge electrodes 152. The second interlayer film 212 may be formed similar to the undercoat 201. Furthermore, the second interlayer film 212 is subjected to etching to form opening portions reaching the source/drain electrodes 208, the wirings 132, and the Tx bridge electrodes 152. These opening portions may be also prepared with dry etching such as the aforementioned plasma etching.

Next, a conductive film is formed to cover the opening portions and processed with etching to form the connection electrode 216, the electrodes 150, and the Rx bridge portions 156 (FIG. 9B). The conductive film can be formed with a sputtering method by using a conductor transmitting visible light, such as ITO and IZO. Alternatively, the conducting film may be formed with a sol-gel method by using an alkoxide of a corresponding metal. Through the aforementioned process, the touch portion 142 is fabricated. Here, in the present specification and claims, one of the main surfaces of the touch portion 142 opposing each other, which is closer to the base film 102 is called a lower surface or a back surface, and the other of the main surfaces which is farther from the base film 102 is called an upper surface or a front surface.

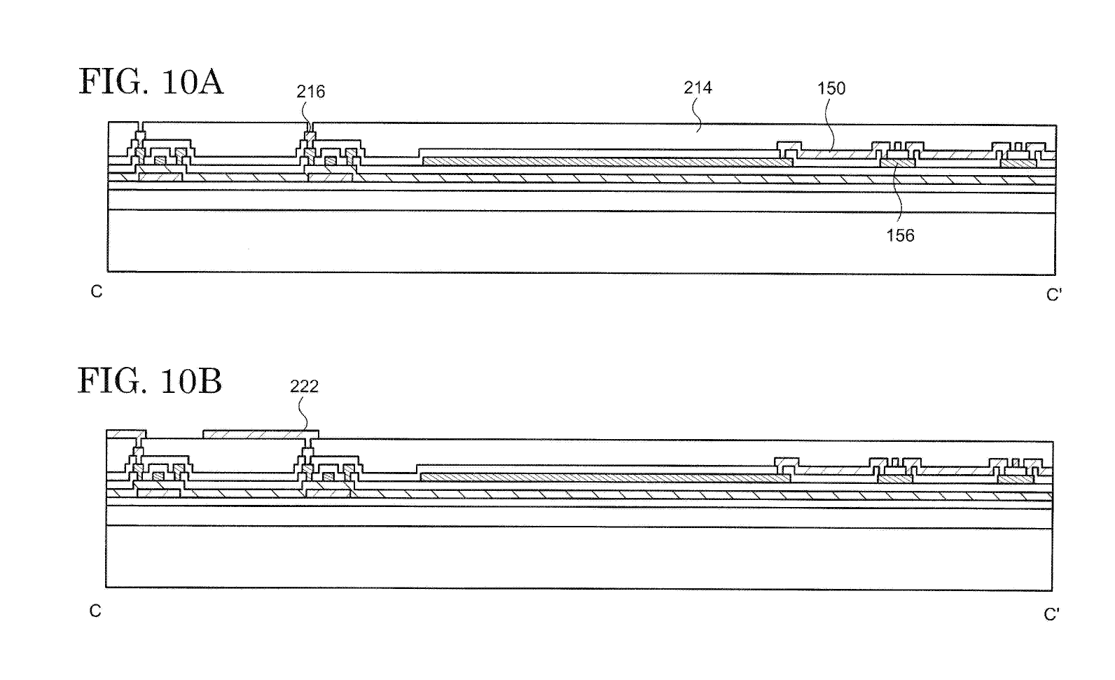

Next, the leveling film 214 is formed to cover the connection electrode 216, the electrodes 150, and the Rx bridge portions 156 (FIG. 10A). The leveling film 214 has a function to absorb depressions and projections caused by the transistor 200 and the touch portion 142 including the Rx bridge portions 156 and the electrodes 150 to provide a flat surface. The leveling film 214 can be formed with an organic insulator. As an organic insulator, a polymer material such as an epoxy resin, an acrylic resin, a polyimide, a polyamide, a polyester, a polycarbonate, and a polysiloxane is represented, and the leveling film 214 can be formed with the aforementioned wet-type film-formation method. The leveling film 214 may have a stacked structure including a layer containing the aforementioned organic insulator and a layer containing an inorganic insulator. In this case, an inorganic insulator including silicon, such as silicon oxide, silicon nitride, silicon nitride oxide, and silicon oxynitride, is represented as an inorganic insulator, and the films including these inorganic insulators can be prepared with a sputtering method or a CVD method.

Next, etching is performed on the leveling film 214 to form an opening portion reaching the connection electrode 216. After that, the first electrode 222 of the light-emitting element 220 is formed over the leveling film 214 with a sputtering method and the like to cover the opening portion (FIG. 10B).

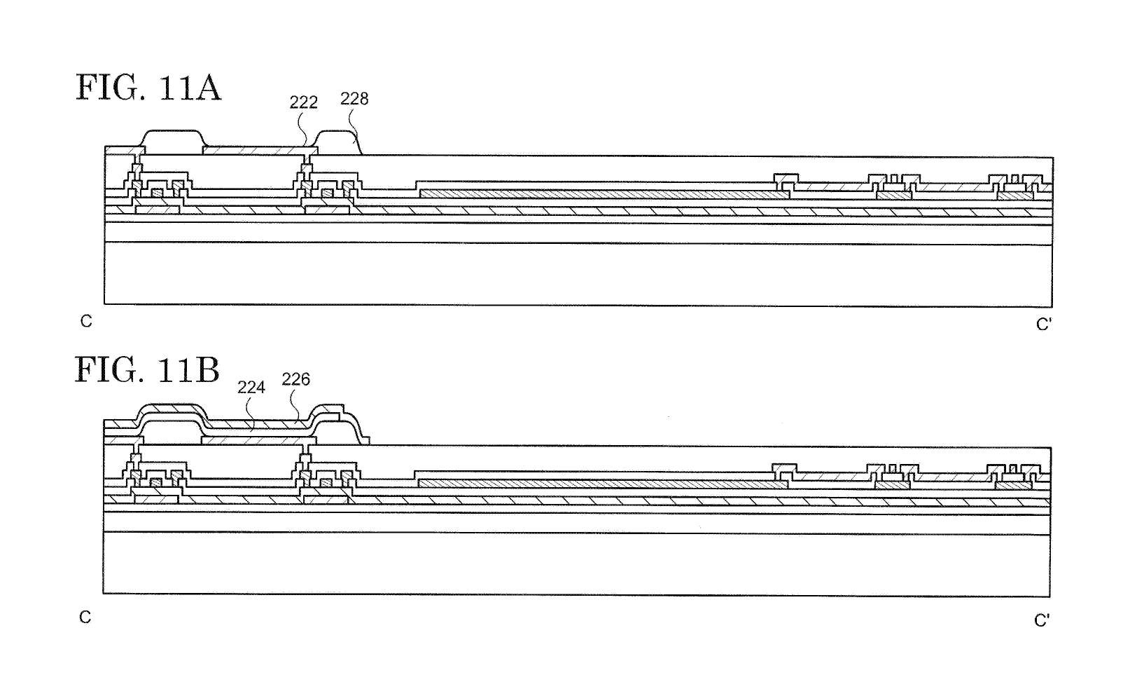

Next, the partition wall 228 is formed so as to cover the edge portion of the first electrode 222 (FIG. 11A). With the partition wall 228, a step caused by the first electrode 222 and the like is absorbed, and the first electrodes 222 of the adjacent pixels 190 can be electrically insulated from each other. The partition wall 228 may be formed with a wet-type film-formation method by using a material applicable in the leveling film 214, such as an epoxy resin and an acrylic resin.

Next, the EL layer 224 and the second electrode 226 of the light-emitting element 220 are formed so as to cover the first electrode 222 and the partition wall 228 (FIG. 11 B). The EL layer 224 may be formed with a single layer or a plurality of layers. For example, the EL layer 224 can be formed by appropriately combining a carrier-injection layer, a carrier-transporting layer, an emission layer, a carrier-blocking layer, an exciton-blocking layer, and the like. Additionally, the EL layer 224 may be different between the adjacent pixels 190. For example, the EL layer 224 may be fabricated so that the emission layer is different but other layers have the same structure between the adjacent pixels 190. On the contrary, the same EL layer 224 may be used in all of the pixels 190. In this case, the EL layer 224 giving white emission is formed so as to be shared by the adjacent pixels 190, and a color filter is used to select a wavelength of light extracted from each pixel 190, for example.

The second electrode 226 can be formed with a similar method as that of the first electrode 222 by using a metal, a conductive oxide having a light-transmitting property, or the like.

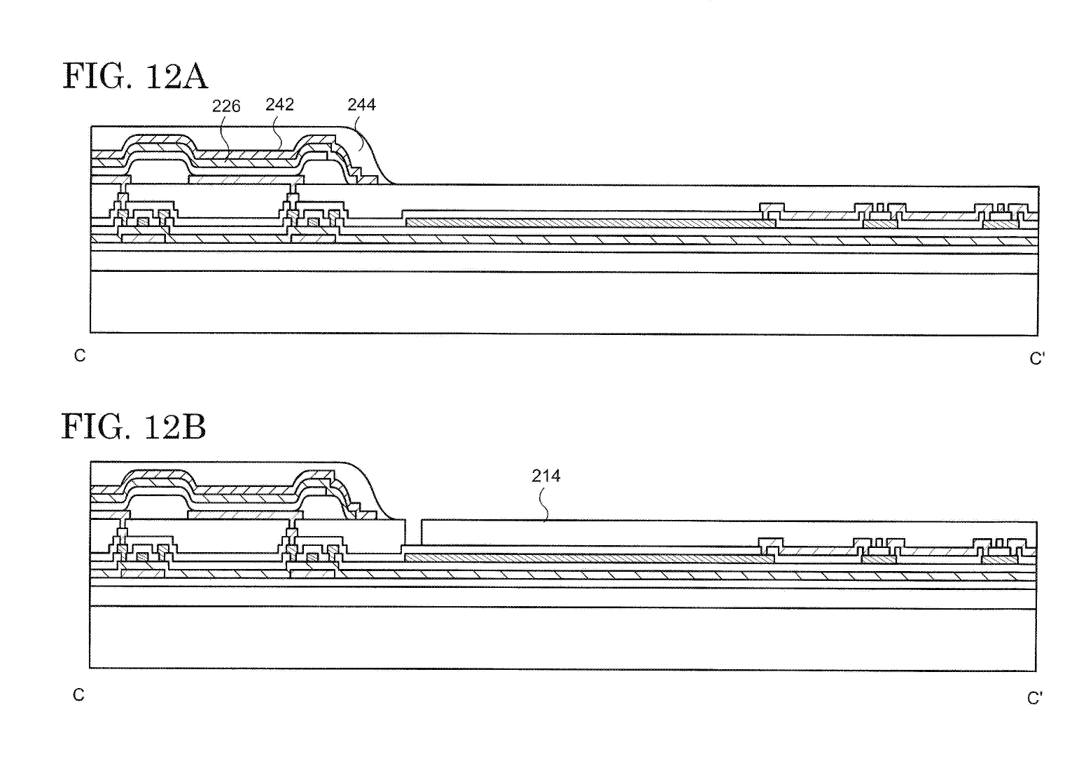

Next, the passivation film 240 is formed. For example, the first layer 242 is first prepared over the second electrode 226 as shown in FIG. 12A. The first layer 242 may contain an inorganic material such as silicon nitride, silicon oxide, silicon nitride oxide, or silicon oxynitride and can be formed with a similar method as that of the undercoat 201. The first layer 242 may be selectively formed over the light-emitting element 220 as shown in FIG. 12A or formed in the boundary region 160 and the touch region 140.

Next, the second layer 244 is formed (FIG. 12A). The second layer 244 may contain an organic resin including an acrylic resin, a polysiloxane, a polyimide, and a polyester. Furthermore, the second layer 244 may be prepared at a thickness to absorb depressions and projections caused by the partition wall 228 providing a flat surface. The second layer 244 may also be formed in a region where the boundary region 160 and the touch region 140 are formed. The second layer 244 can be formed with the aforementioned wet-type film-formation method. Alternatively, the second layer 244 may be formed by atomizing or vaporizing oligomers serving as a raw material of the aforementioned polymer materials under a reduced pressure, spraying the first layer 244 with the oligomers, and then polymerizing the oligomers.

Next, in the region between the pixel 190 of the display region 120 closest to the boundary region 160 and the boundary region 160, the opening portion is formed in the leveling film 214 (FIG. 12B). The opening portion may be prepared with the aforementioned dry etching and the like.

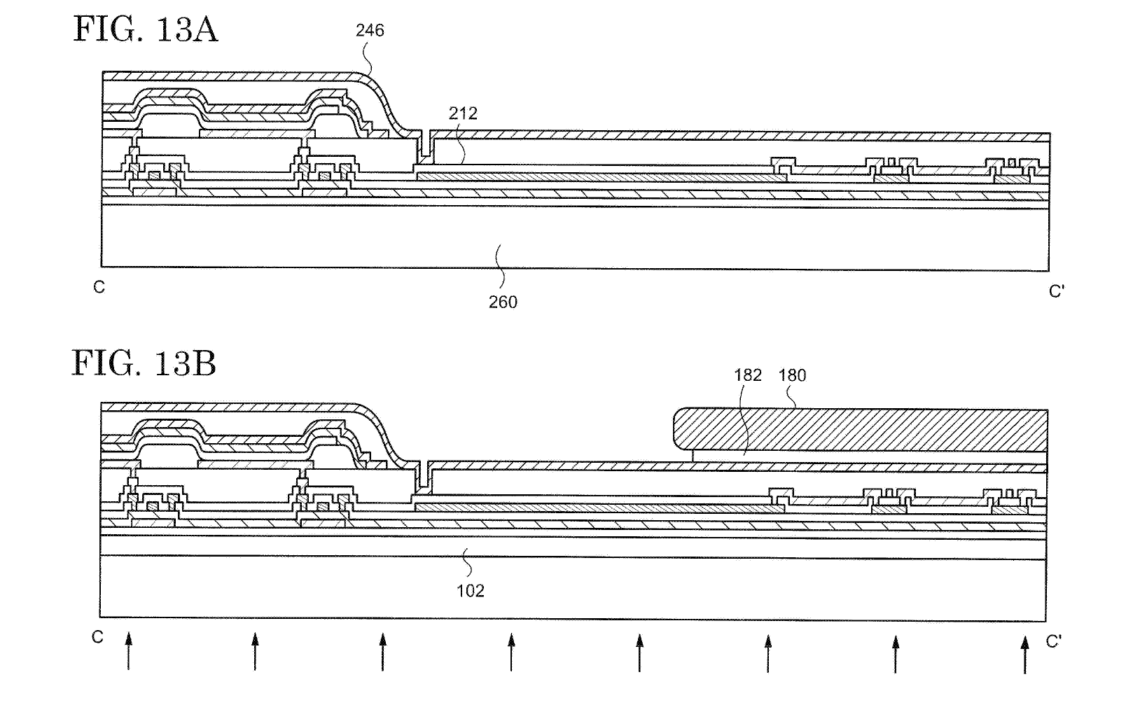

After that, the third layer 246 is formed (FIG. 13A). The third layer 246 may have a similar structure and can be prepared with a similar method as those of the first layer 242. The third layer 242 may be formed not only over the opening portion provided in the leveling film 214 and the light-emitting element 220 but also over the boundary region 160 and the touch region 140. The third layer 246 is in contact with the second interlayer film 212 in the opening portion. This structure disconnects the leveling film 214. With this structure, it is possible to prevent diffusion of impurities from the boundary region 160 to the display region 120 through the leveling film 214, thereby improving reliability of the light-emitting element 220.

After that, the supporting substrate 260 is separated. For example, light such as a laser is applied from a side of the supporting substrate 260 to decrease adhesion between the supporting substrate 260 and the base film 102. Simultaneously, the transparent substrate 180 may be adhered to the touch region 140 by using the adhesion layer 182 (FIG. 13B). As the adhesion layer 182, a photo-curable resin, a thermosetting resin, and the like can be used. As the transparent substrate 180, a substrate containing a material transmitting visible light, such as a glass substrate and a plastic substrate, can be employed.

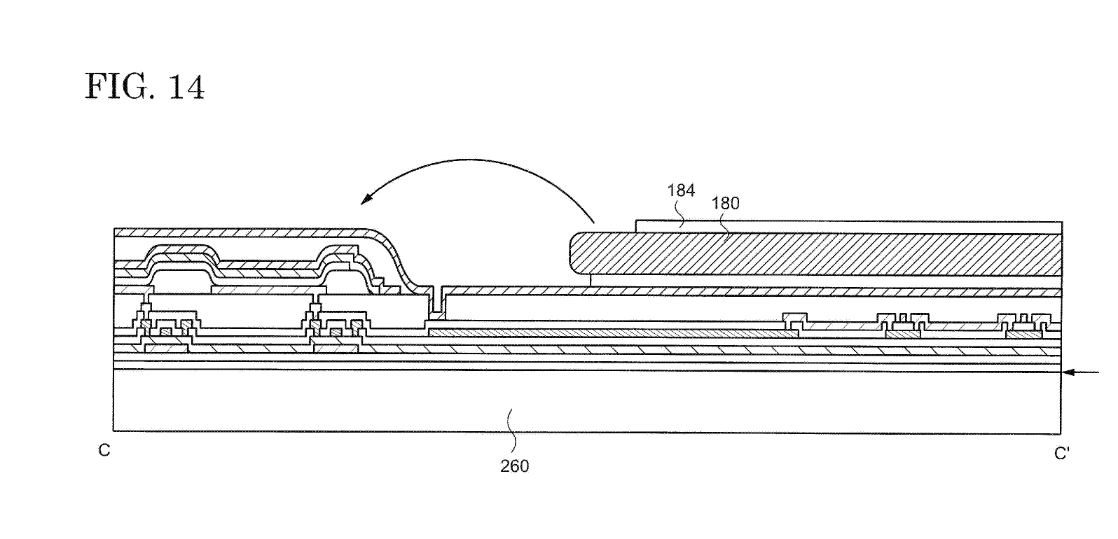

After adhering the transparent substrate 180 to the touch region 140, the adhesion layer 184 is further applied on the transparent substrate 180 or the display region 120, and the transparent substrate 180 is transferred as indicated by a curved arrow in FIG. 14. Namely, the base film 102 is folded so that a back surface of the touch portion 142 opposes the image-display portion 122 through the touch portion 142. Pealing occurs at an interface with reduced adhesion (a straight arrow in FIG. 14) between the supporting substrate 260 and the base film 102. Adhesion of the transparent substrate 180 to the display region 120 via the adhesion layer 184 results in the formation of the display device 100 having the structure shown in FIG. 5.

As described above, application of the manufacturing method of the present embodiment enables the simultaneous formation of the display region 120 and the touch region 140. Therefore, the process of the display device 100 can be simplified. As a result, the display device 100 installed with the touch portion 142 over the image-display portion 122 can be manufactured at low cost.

### Third Embodiment

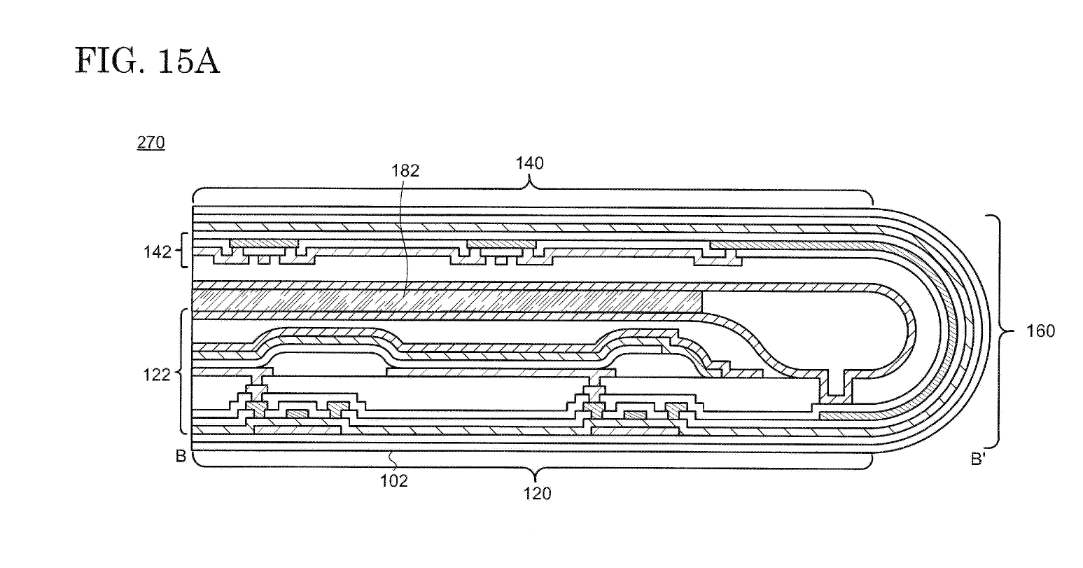

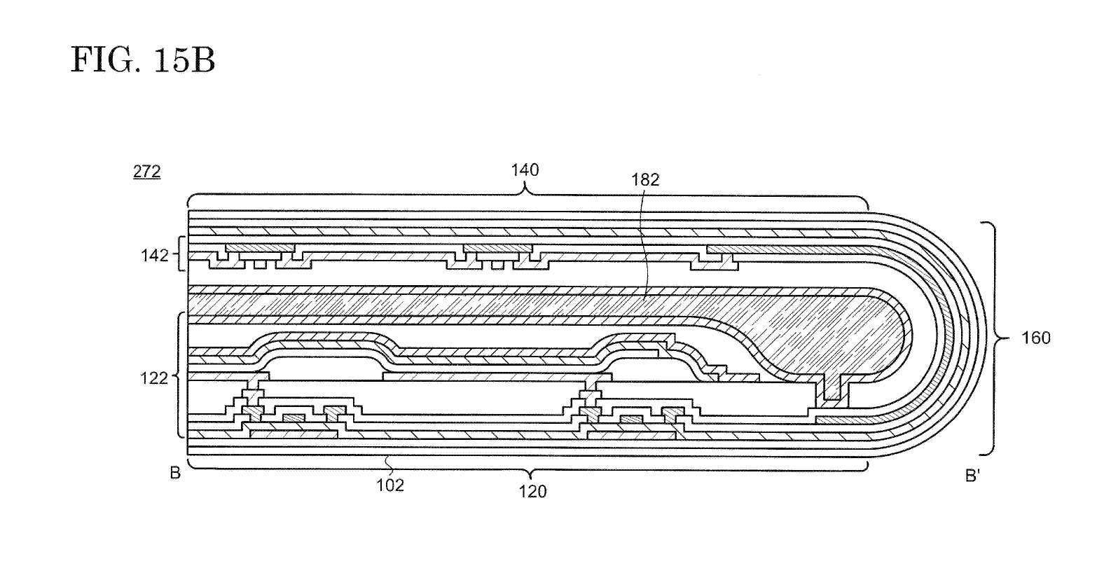

In the present embodiment, display devices different in structure from the display device 100 shown in the First Embodiment are explained by using FIG. 15A to FIG. 17. Contents which are the same as those described in the First and Second Embodiments may be omitted. FIG. 15A to FIG. 17 are schematic cross-sectional views along a chain line B-B′ in FIG. 1A.

A display device 270 shown in FIG. 15A is different from the display device 100 shown in the First Embodiment in that the transparent substrate 180 is not included. For example, when the base film 102 is thin or flexibility thereof is high, the boundary region 160 can be largely folded. Thus, the display region 120 and the touch region 140 can be tightly adhered with only the adhesion layer 182 even though the transparent substrate 180 is not used. This structure allows the production of a flexible display device installed with a touch panel.

Note that, similar to the display device 272 shown in FIG. 15B, the adhesion layer 182 may be provided so as to fill the entire region enclosed by the display region 120, the touch region 140, and the boundary region 160 by which strength of the boundary region 160 and a periphery thereof can be increased.

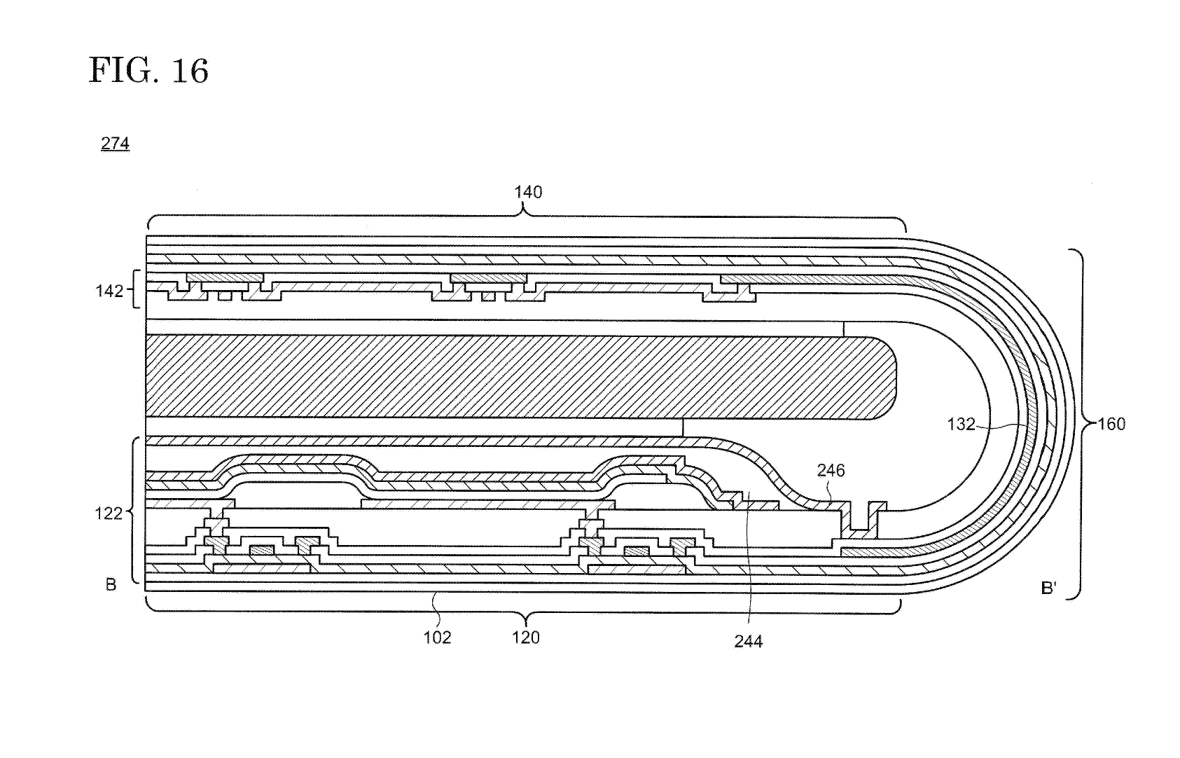

A display device 274 shown in FIG. 16 is different from the display device 100 shown in the First Embodiment in that the third layer 246 of the passivation film 240 is selectively provided in the display region 120 and is not disposed in the boundary region 160 and the touch region 140. As described in the Second Embodiment, since the third layer 246 can include an inorganic material, the third layer 246 is more rigid than the second layer 244 and the like which can include a polymer material. Therefore, the selective formation of the third layer 246 in the display region 120 offers high flexibility to the boundary region 160, allowing the boundary region 160 to be readily folded. Additionally, an inorganic material usable in the third layer 246 has a higher refractive index compared with a polymer material. Hence, visibility of the image-display portion 122 can be improved without providing the third layer 246 in the touch region 140. Moreover, the wirings 132 can be arranged close to a center line (a line passing through a center between the bottom surface and the upper surface of the boundary region 160) in the boundary region 160.

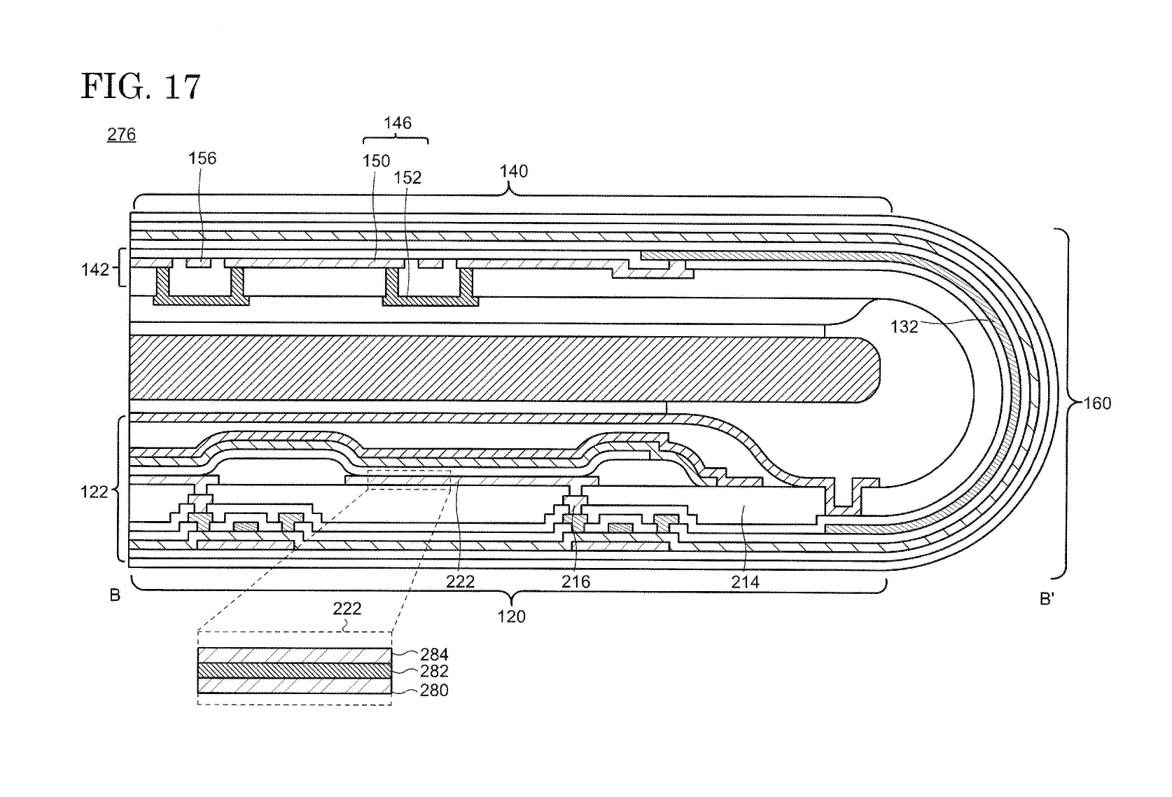

A display device 276 shown in FIG. 17 is different in structure of the Tx wiring and the Rx wiring of the touch portion 142 from the display device 274 shown in FIG. 16. Specifically, the electrodes 150 included in the Tx wirings 146 and the Rx wirings 148 and the Rx bridge portions 156 included in the Rx wirings 148 (see FIG. 3) exist in the same layer as the connection electrode 216 of the display region 120. On the other hand, a part of the Tx bridge electrodes 152 is located over the leveling film 214. Furthermore, the Tx bridge electrodes 152 contain the layer included in the first electrode 222 of the light-emitting element 220. Hence, the Tx bridge electrodes 152 exist in the same layer as the first electrode 222. Specifically, as shown in an enlarged figure in FIG. 17, the first electrode 222 possesses a first layer 280, a second layer 282, and a third layer 284, where the first layer 280 and the third layer 284 include a conductive oxide with a light-transmitting property and the second layer 282 includes a metal with a high reflectance, such as silver or aluminum. The Tx bridge electrodes 152 contain a metal included in the second layer 282 and exist in the same layer as the second layer 282.

With this structure, the electrodes 150 are arranged at a position farther from the display region 120, that is, a position closer to a user than the Tx bridge electrodes 152. Therefore, visibility of the image-display portion 122 is increased, and an image with higher quality is provided.

### Fourth Embodiment

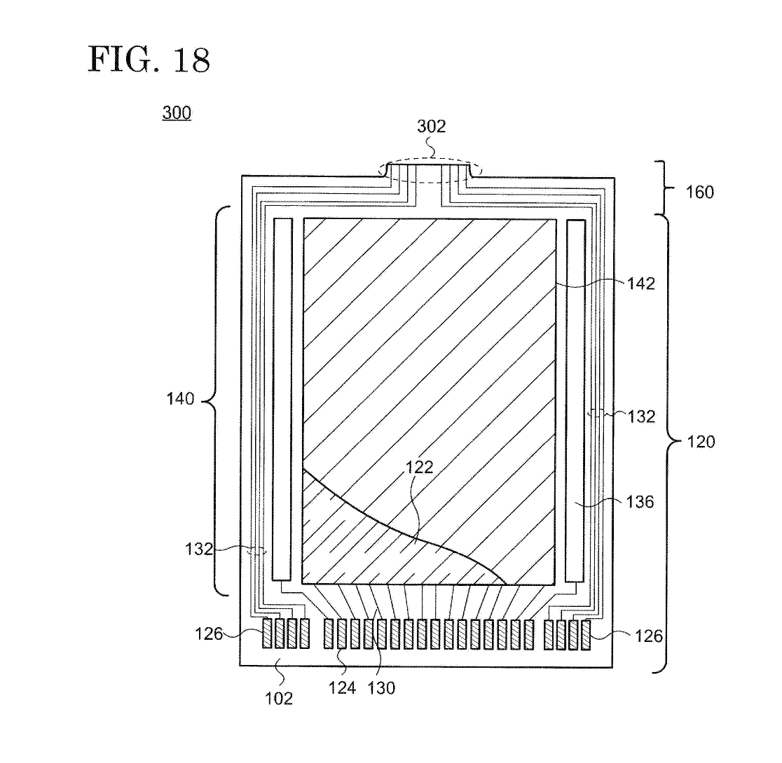

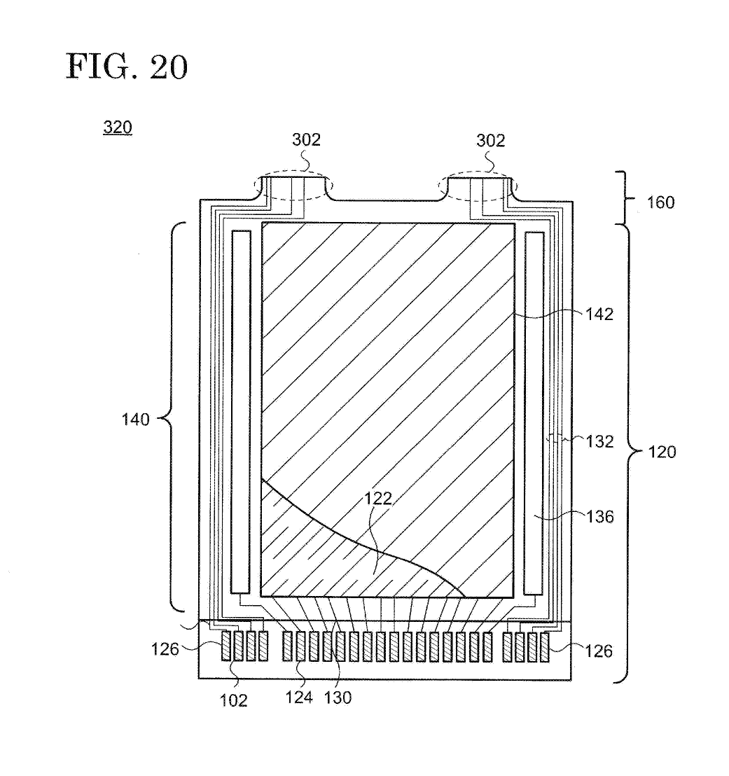

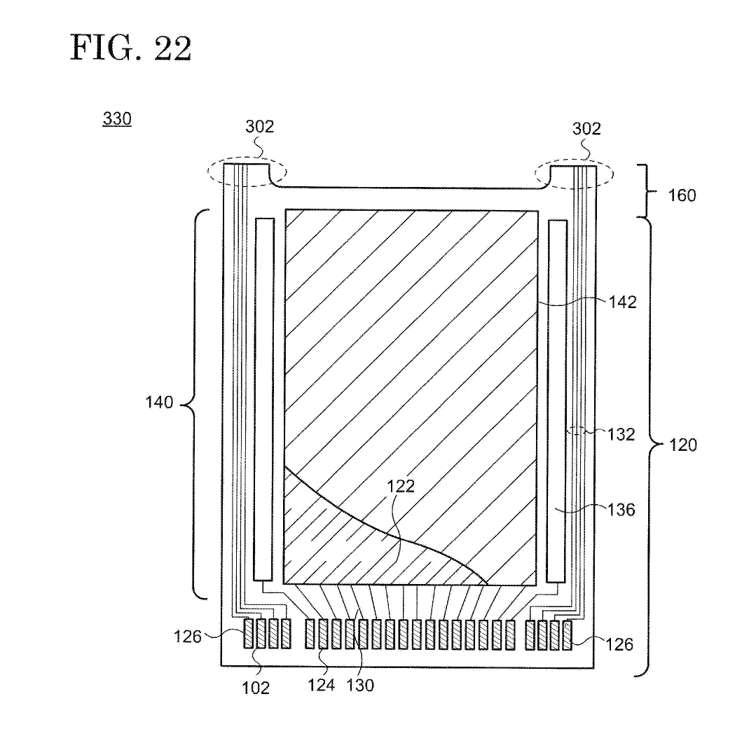

In this embodiment, display devices different in structure from the display devices 270, 272, 274, and 276 of the First Embodiment are explained by using FIG. 18 to FIG. 23. The structures which are the same as those of the First to Third Embodiments may be omitted. Note that, for clarity, the base film 102 of the touch region 140 provided over the display region 120 is not illustrated in FIG. 18, FIG. 20, and FIG. 22.

A top view of a display device 300 which is a display device of the present embodiment is shown in FIG. 18. As shown in FIG. 18, the base film 102 possesses the display region 120, the touch region 140, and the boundary region 160 between the display region 120 and the touch region 140. The touch region 140 is located over and overlaps with the display region 120. The display device 300 is different in structure of the boundary region 160 from the display device 100.

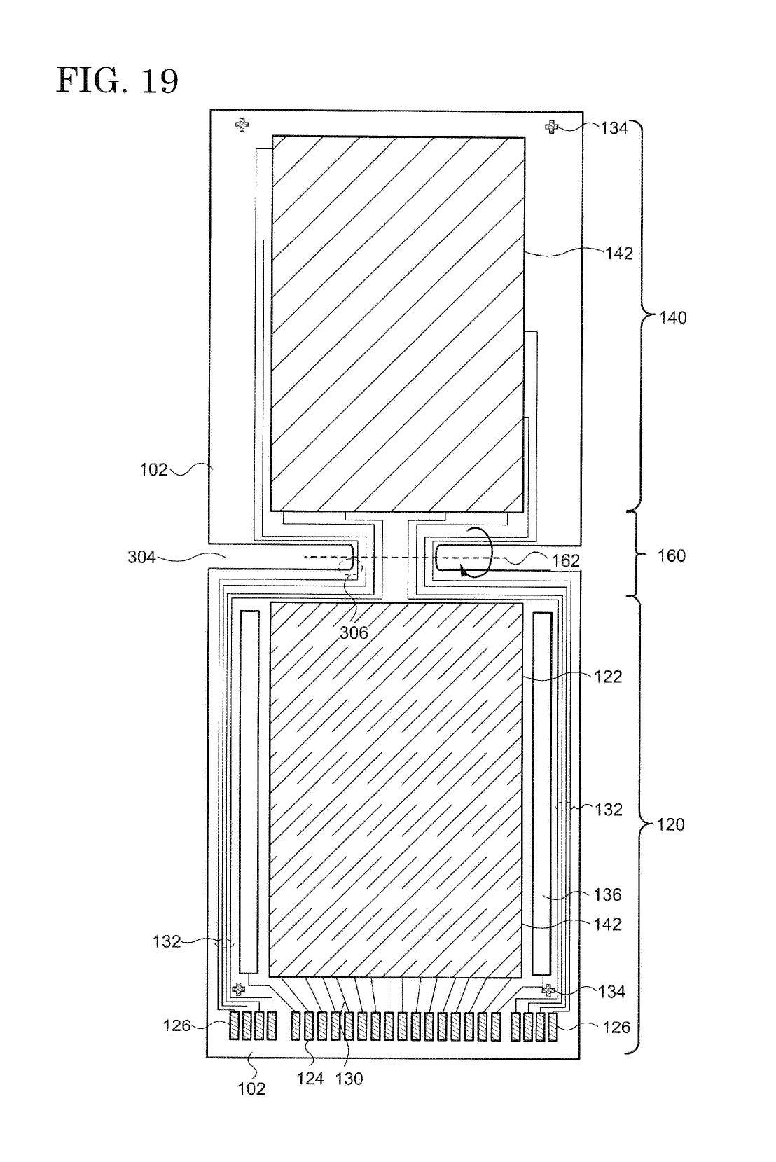

Specifically, as shown in FIG. 18, the boundary region 160 has a portion (protruding portion) 302 protruding in a direction parallel to an upper surface or a lower surface of the base film 102 from a region where the image-display portion 122 and the touch portion 142 overlap with each other. A width of the protruding portion 302 is smaller than a width (a width in a direction of an axis 162 in FIG. 19) of the base film 102 in the display region 120 and the touch region 140. The wirings 132 connecting the second terminals 126 to the touch portion 142 extend to the touch region 140 through the protruding portion 302 of the boundary region 160. Note that, in FIG. 18, the protruding portion 302 is located at a center of one side of the display device 300. However, the protruding portion 302 may be arranged at a position shifted in any direction along this side.

A shape and arrangement of the protruding portion 302 is not limited to those of the display device 300. For example, the boundary region 160 may have two protruding portions 302 as demonstrated by the display device 320 shown in FIG. 20. Alternatively, similar to a display device 330 shown in FIG. 22, two protruding portions 302 may be provided at edge portions of the base film 102 in the boundary region 160. In these display devices 320 and 330, the wirings 132 connecting the second terminals 126 to the touch portion 142 extend to the touch region 140 through the two protruding portions 302 in the boundary region 160. In this case, the number of the wirings 132 arranged in the two protruding portions 302 may be different from each other. Additionally, the widths of the two protruding portions 302 may be different from each other.

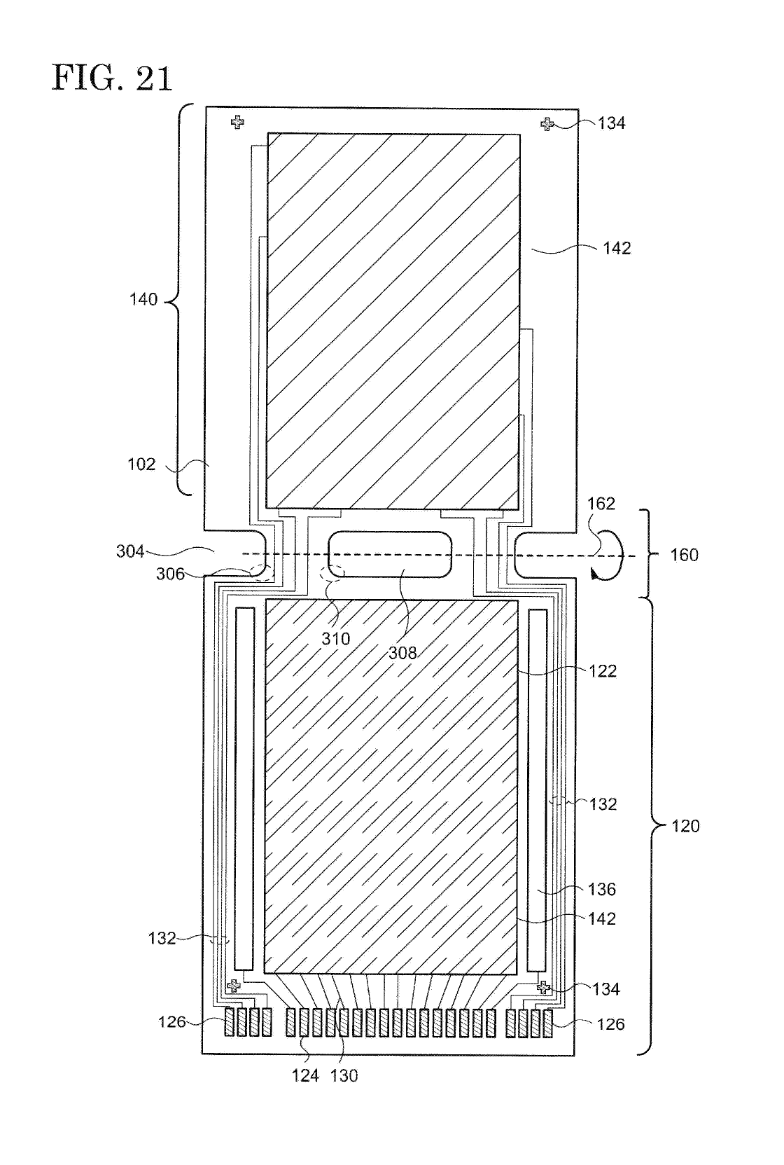

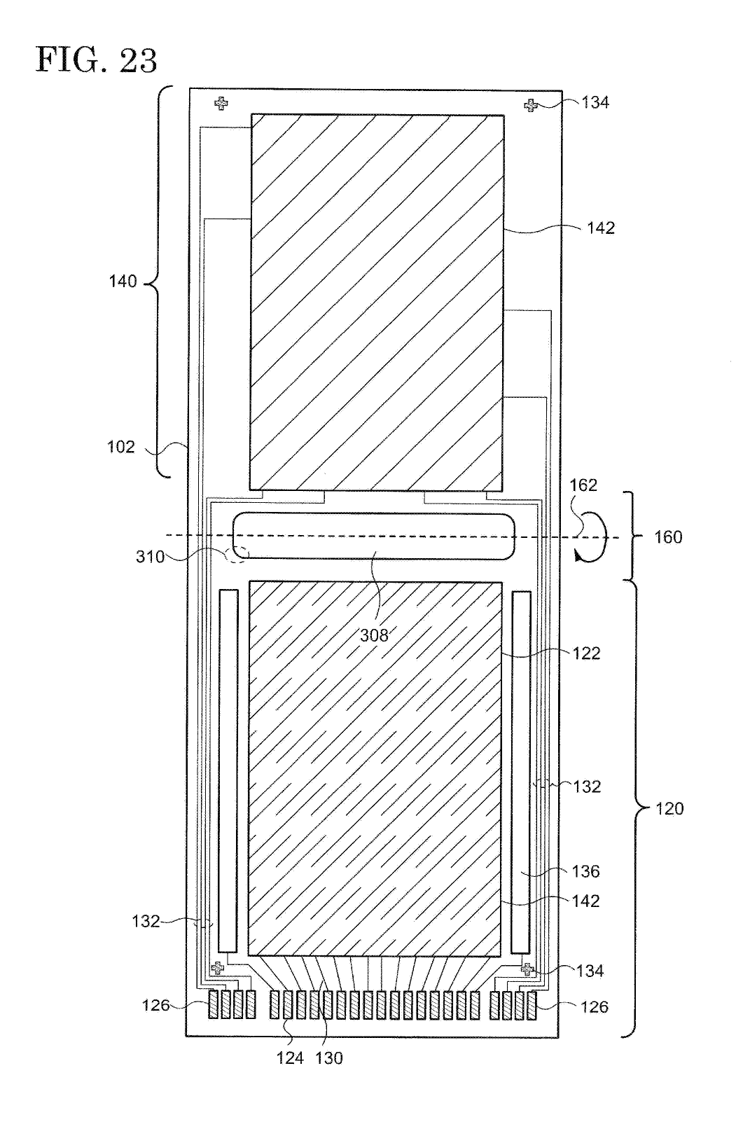

As shown in FIG. 19, the display device 300 having such a structure can be fabricated by providing two slits 304 to the base film 102 in the boundary region 160 to reduce a width of a part of the base film 102 and then folding the base film 102 along the axis 162 passing through the region with the small width. Similarly, as shown in FIG. 21, the display device 320 can be fabricated by providing two slits 304 and an opening portion 308 therebetween to reduce the width of a part of the base film 102 and then folding the base film 102 at this part along the axis 162. A shown in FIG. 23, the display device 330 can be fabricated by providing the boundary region 160 with an opening portion 308 having a length which is equal to or longer than the widths of the image-display portion 122 and the touch portion 142 and then folding the base film 102 at this part along the axis 162.

Alignment markers 134 are formed in the display region 120 and the touch region 140, and the base film 102 is folded so that the alignment markers 134 overlap with each other, by which the touch region 140 can be stacked over the display region 120 at high reproducibility and accuracy.

When the display device 300 or 320 is fabricated, a tip portion of the slit 304, that is, a corner 306 of the slit 304 preferably has a curved shape (FIG. 19, FIG. 21). Similarly, a corner 310 of the opening portion 308 formed when the display device 320 or 330 is fabricated preferably has a curved shape (FIG. 21, FIG. 23). The formation of such a curved shape at the tip portion of the slit 304 and the corner 310 of the opening portion 308 prevents damage to the base film 102 when the base film 102 is folded, by which disconnection of the display region 120 from the touch region 140 can be prevented.

In the display devices 300, 320, and 330, since the width of the folded portion in the boundary region 160 is small, a force which is applied when the folded base film 102 recovers to its original shape (restoration force) can be reduced, by which the folding process can be facilitated and the shapes of the display devices 300, 320, and 330 can be stably maintained.

### Fifth Embodiment

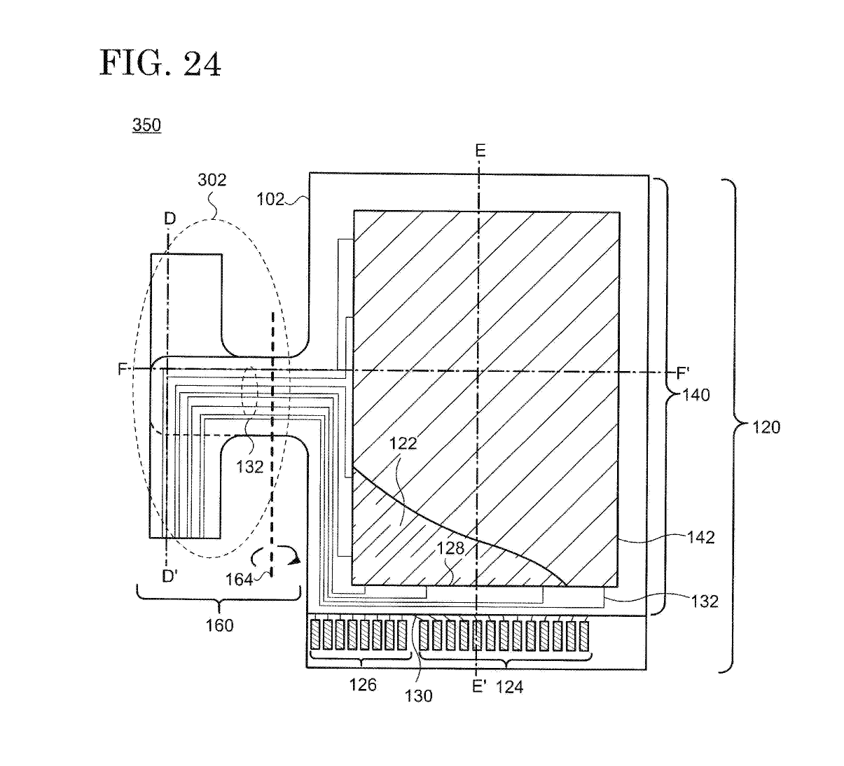

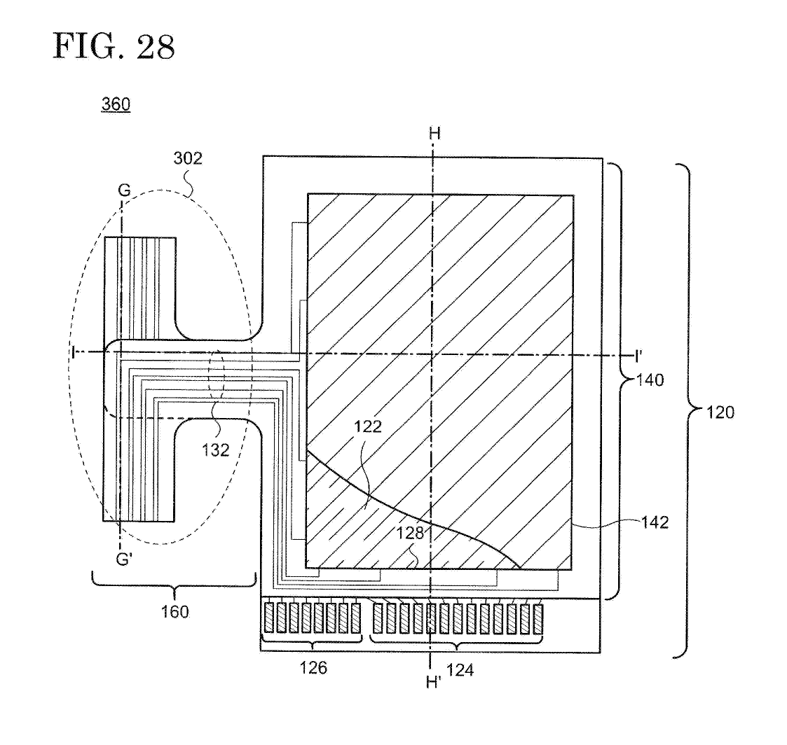

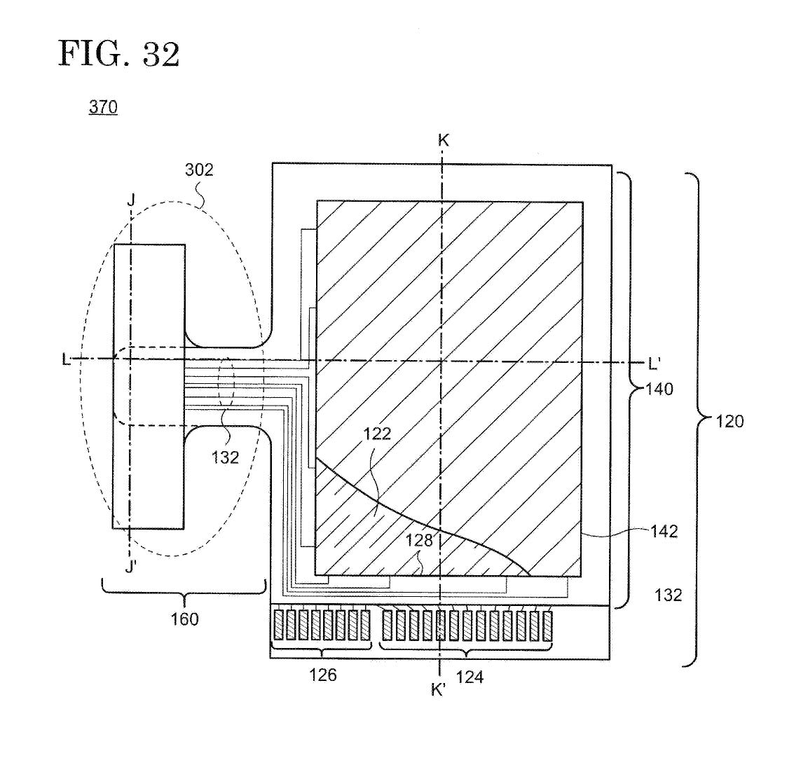

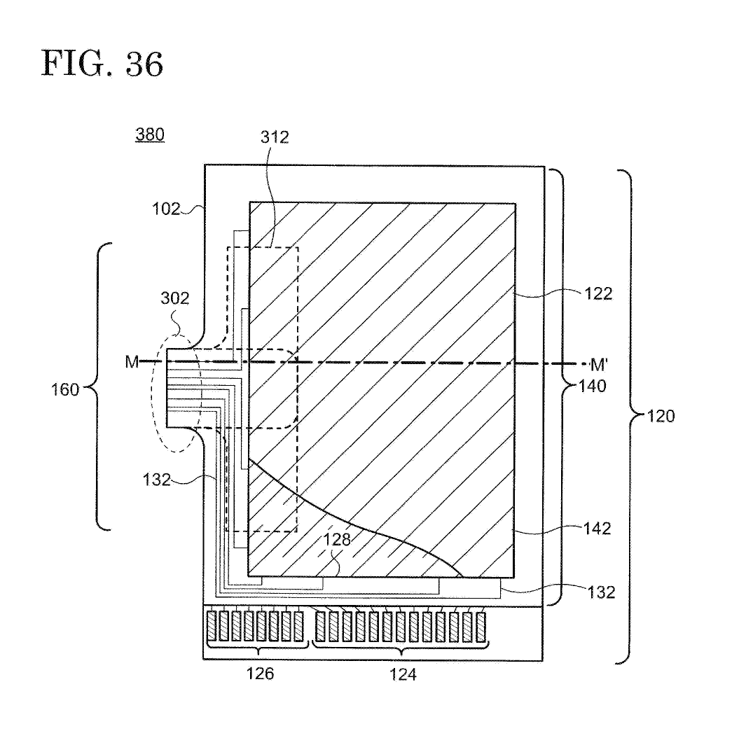

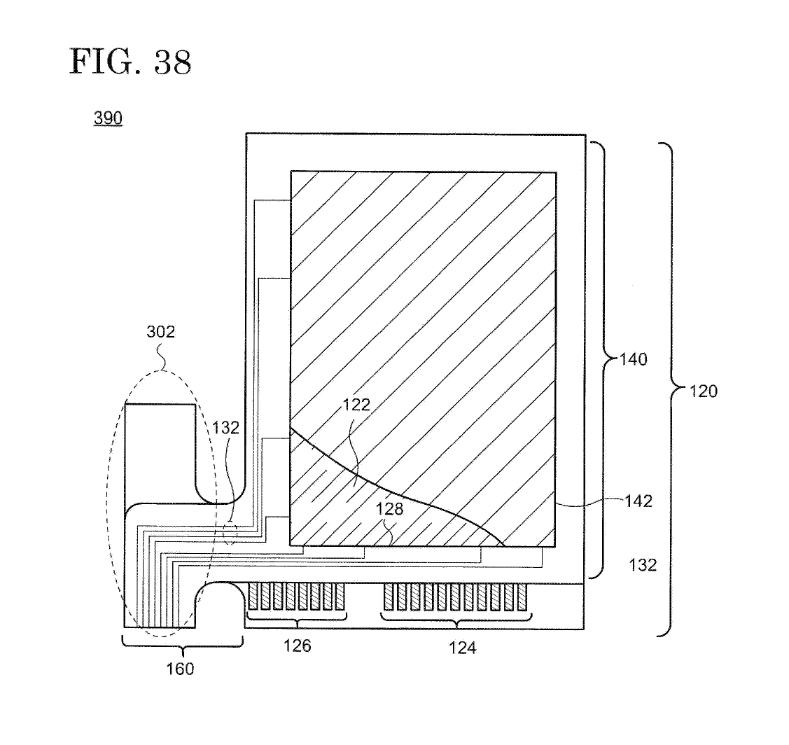

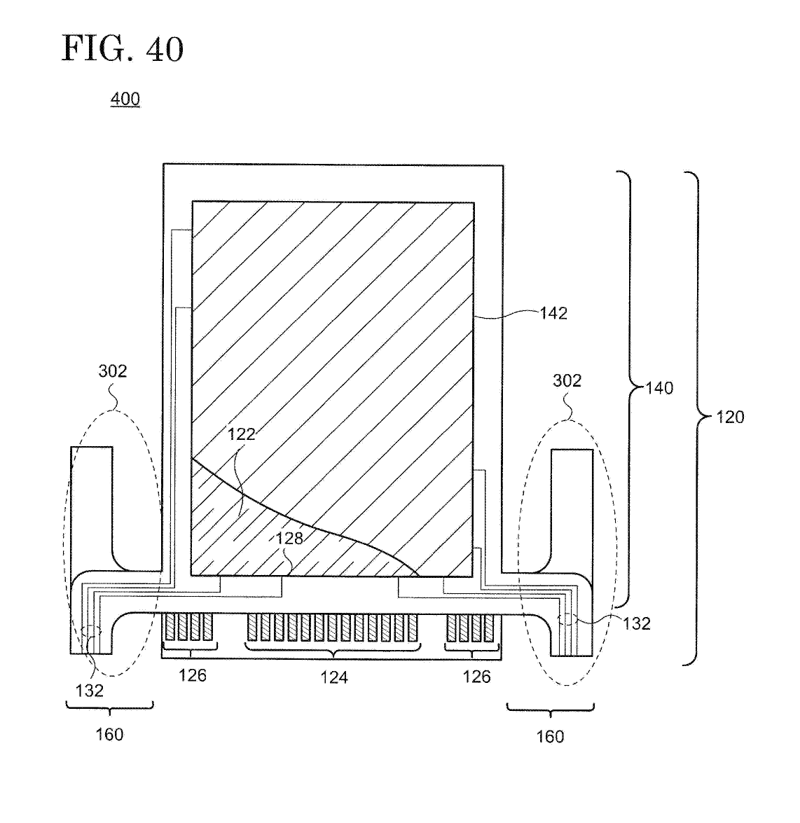

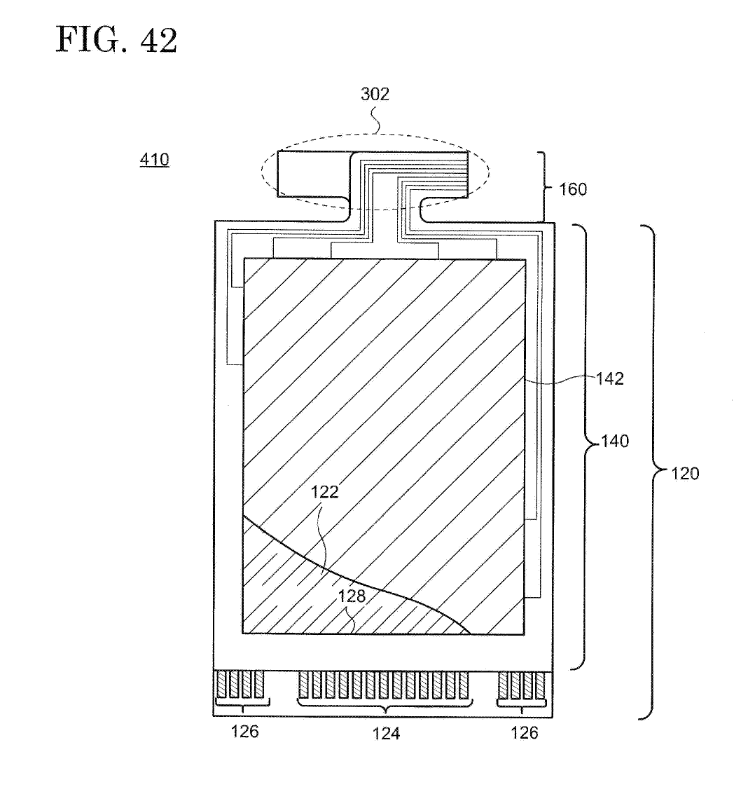

In this embodiment, display devices different in structure from the display devices of the First to Fourth Embodiments are explained by using FIG. 24 to FIG. 43. The structures which are the same as those of the First to Fourth Embodiments may be omitted. Note that, for clarity, the base film 102 of the touch region 140 provided over the display region 120 is not illustrated in FIG. 24, FIG. 28, FIG. 32, FIG. 36, FIG. 38, FIG. 40, and FIG. 42.

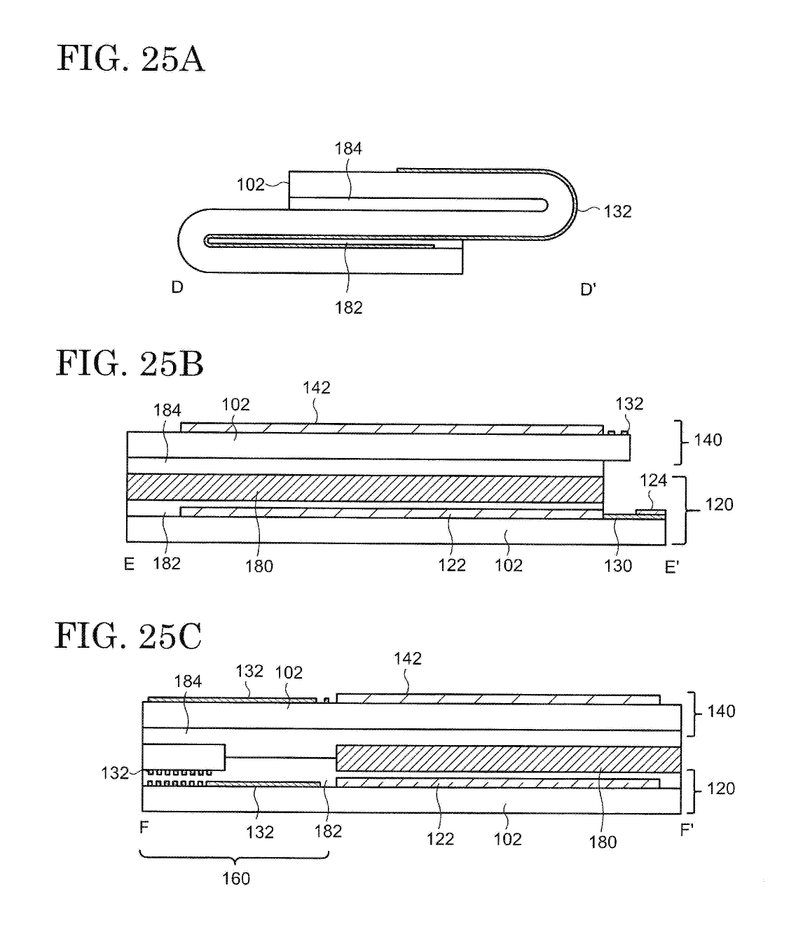

A top view of a display device 350 which is a display device of the present embodiment is shown in FIG. 24, and cross-sectional views along chain lines D-D′, E-E′, and F-F′ of FIG. 24 are illustrated in FIG. 25A, FIG. 25B, and FIG. 25C, respectively. As shown in FIG. 24 and FIG. 25A to FIG. 25C, the base film 102 has the display region 120, the touch region 140, and the boundary region 160 between the display region 120 and the touch region 140. The touch region 140 is located over and overlaps with the display region 120. The display device 350 is different from the display device 100 in position and structure of the boundary region 160 and in vertical relationship between the touch portion 142 and the base film 102.

Specifically, as shown in FIG. 24, the boundary region has the protruding portion 302. The protruding portion 302 protrudes in a direction parallel to the first side 128 from a region where the display region 120 and the touch region 140 overlap with each other. The wirings 132 connecting the second terminals 126 to the touch portion 142 extend to the touch region 140 from the display region 120 through the protruding portion 302. Additionally, the protruding portion 302 has a three-folded structure. For example, as shown in FIG. 25A, the base film 102 has a three-folded structure having two bent portions, and the wirings 132 are folded according to the folded structure of the base film 102.

On the other hand, as shown in FIG. 25B and FIG. 25C, although the touch region 140 is located over and overlaps with the display region 120, the touch portion 142 is located over the base film 102 of the touch region 140. Hence, the transparent substrate 180 is not directly adhered to the touch portion 142 but adhered to the base film 102 in the touch region 140 with the adhesion layer 184. Therefore, the base film 102 has a three-layer structure in the protruding portion 302 but has a two-layer structure in the region where the display region 120 overlaps with the touch region 140

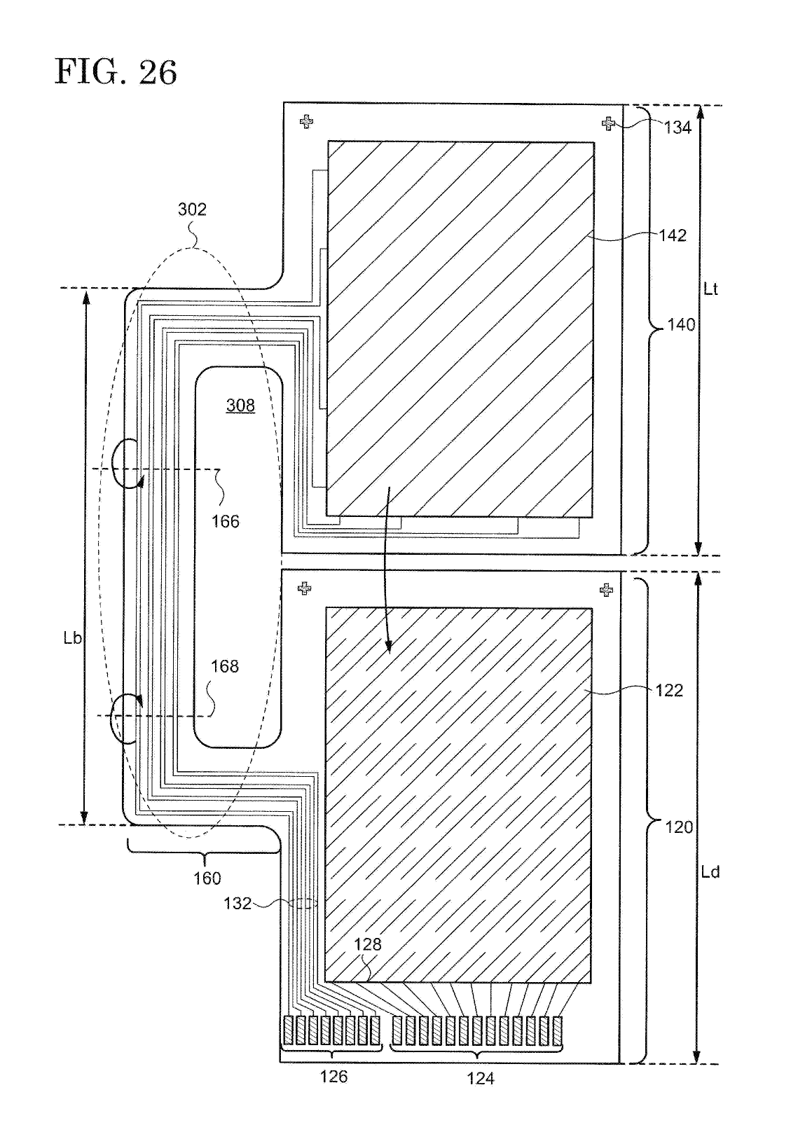

The display device 350 having such a structure can be fabricated by the following method. For example, as shown in FIG. 26, the image-display portion 122 and the touch portion 142 are respectively formed in the display region 120 and the touch region 140 over the base film 102. The boundary region 160 is not arranged to be sandwiched between the display region 120 and the touch region 140, but arranged so as to be in contact with side surfaces of the display region 120 and the touch region 140, which are not sandwiched by the display region 120 and the touch region 140. Here, the side surfaces of the display region 120 and the touch region 140, which are in contact with the boundary region 160, are perpendicular to the first side 128 of the image-display portion 122. A length Lb (a length in a direction perpendicular to the first side 128) of the boundary region 160 is ½ or more of a summation of a length Ld of the side surface of the display region 120 and a length Lt of the side surface of the touch region 140. Moreover, the opening portion 308 in contact with the side surfaces of the display region 120 and the touch region 140 is provided in the boundary region 160. Similar to the Fourth Embodiment, it is preferred that the corner of the opening portion 308 have a curved shape.

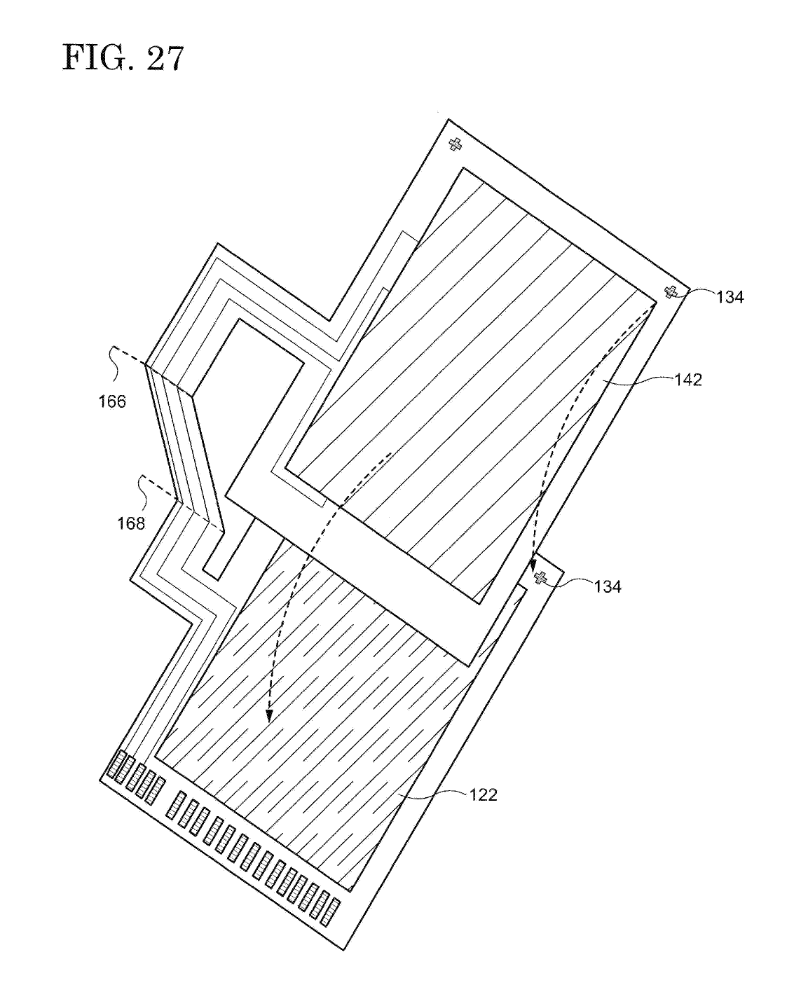

After that, the base film 102 is folded so that the front surface of the touch portion 142 overlaps with the image-display portion 122 with the touch portion 142 interposed therebetween. Specifically, as indicated by an arrow in the drawing, the boundary region 160 is folded twice along axes 166 and 168. Here, the axes 166 and 168 each intersect the opening portion 308, and the axis 166 is closer to the touch region 140 than the other. More specifically, as shown in FIG. 27, the boundary region 160 is folded so that a portion of the boundary region 160 further up than the axis 166 covers a portion lower than the axis 166 and that a portion of the boundary region 166 between the axes 166 and 168 covers a portion of the boundary region 160 lower than the axis 168. In this case, the touch region 140 is placed over the display region 120 so that the alignment markers in the display region 120 and the touch region 140 overlap with each other, thereby giving the display device 350.

Note that, in FIG. 26 and FIG. 27, a case is illustrated where the display device 350 is fabricated from a state in which the touch region 140 is positioned over the display region 120 in the developed state.

However, the display device 350 may be fabricated from a state where the display region 120 is positioned over the touch region 140. In this case, the boundary region 160 is folded so that the portion of the boundary region 160 lower than the axis 168 covers a portion further up than the axis 168 and that the portion of the boundary region 166 between the axes 166 and 168 covers the portion of the boundary region 166 further up than the axis 166.

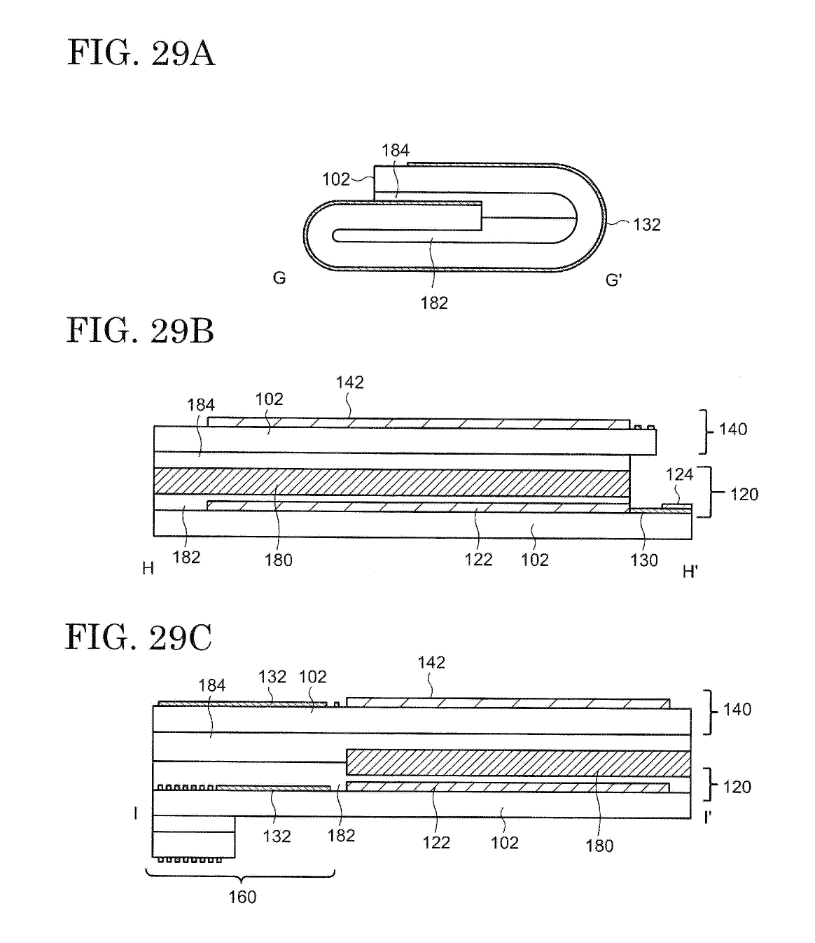

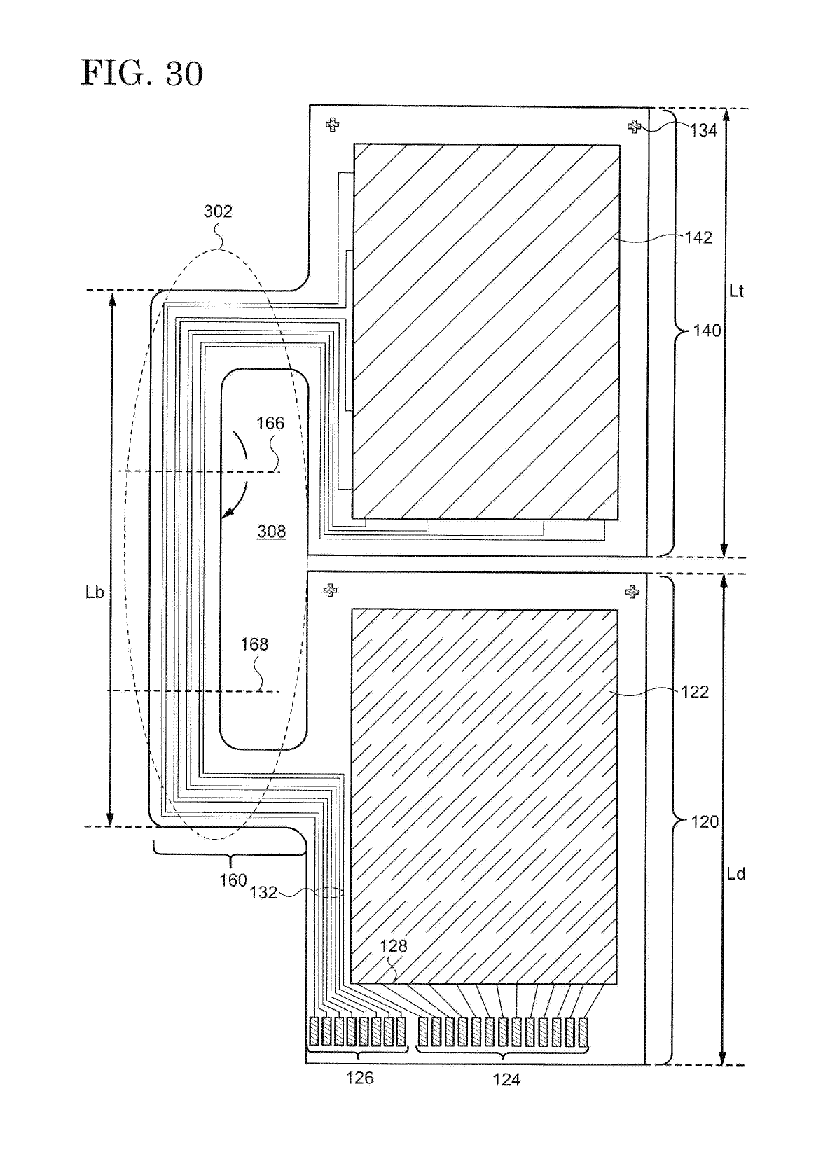

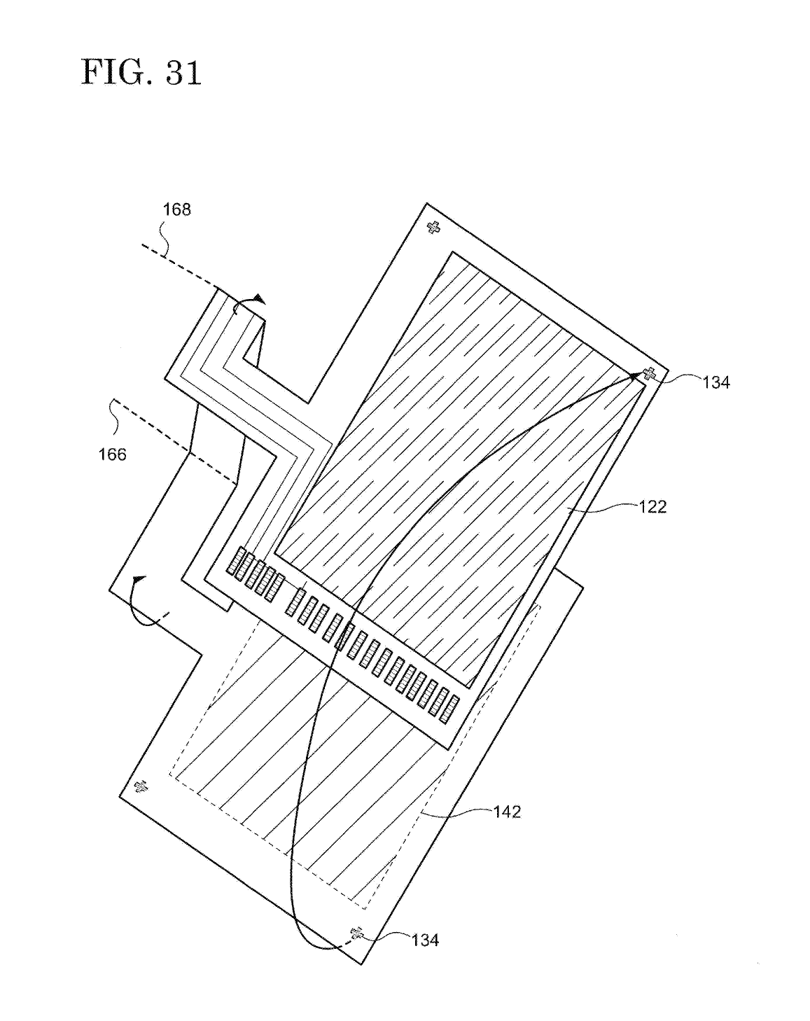

A display device of the present embodiment may be a display device 360 having a structure shown in FIG. 28, FIG. 29A, FIG. 29B, and FIG. 29C. FIG. 29A, FIG. 29B, and FIG. 29C are schematic cross-sectional views along chain lines G-G′, H-H′, and I-I′ of FIG. 28, respectively. The display device 360 is different from the display device 350 in the folding mode of the boundary region 160. More specifically, the boundary region 160 is folded along the axis 166 so that the portion of the boundary region 160 further up than the axis 166 in FIG. 30 is arranged under the portion lower than the axis 168 and that the touch portion 142 is located under the base film 102 of the touch region 140 (FIG. 31). Furthermore, as indicated by an arrow in FIG. 31, the boundary region 160 is folded along the axes 166 and 168, and the touch region 140 is arranged over the display region 120 so that the alignment markers 134 in the touch region 140 match the alignment markers 134 in the display region 120.

Such deformation allows production of the display device 360. Hence, as shown in FIG. 29C, a part of the boundary region 160 is positioned under the display region 120.

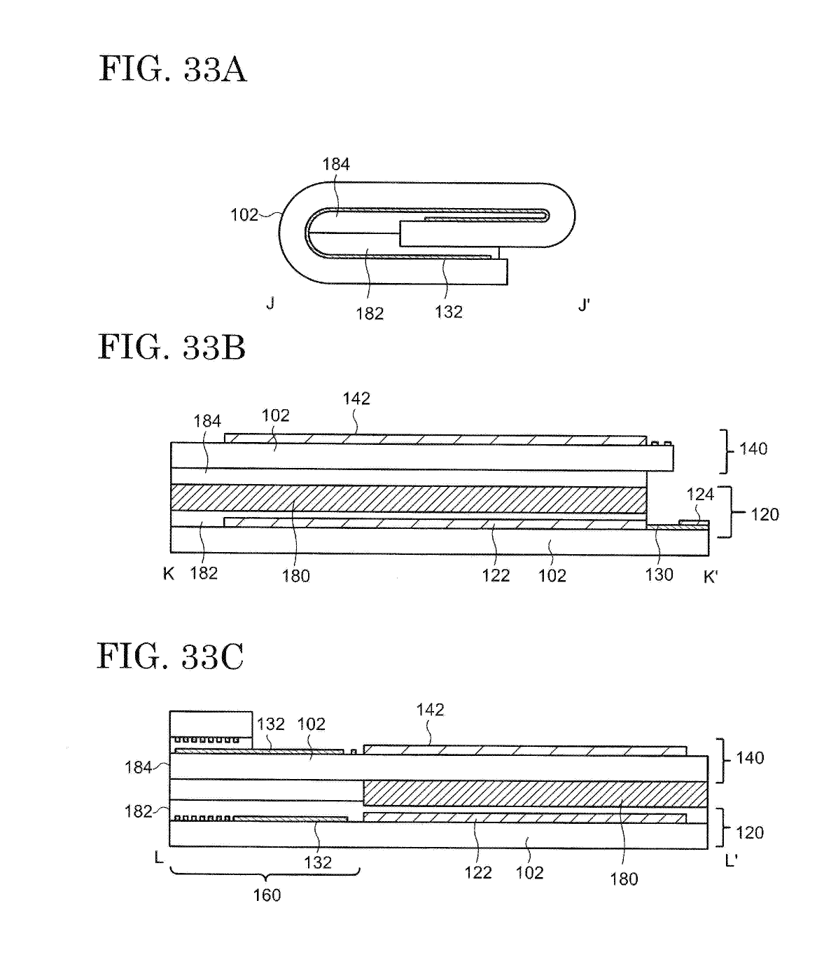

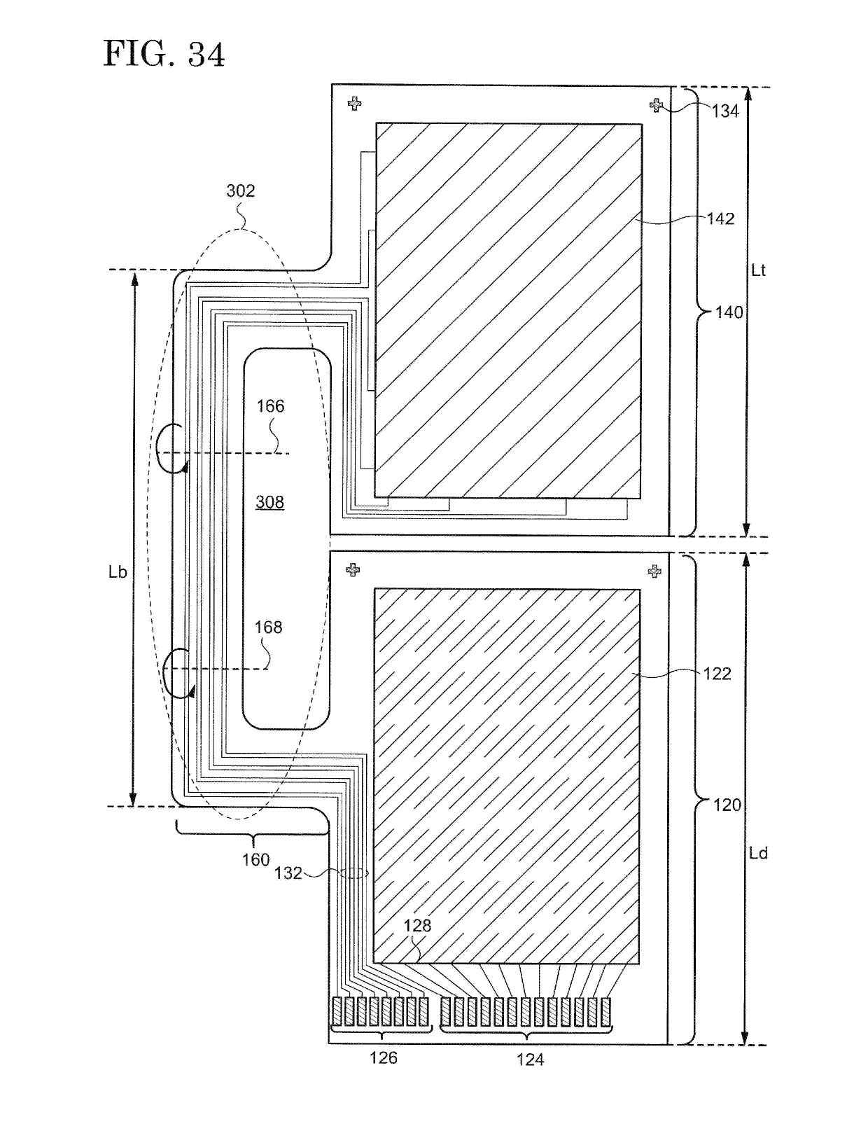

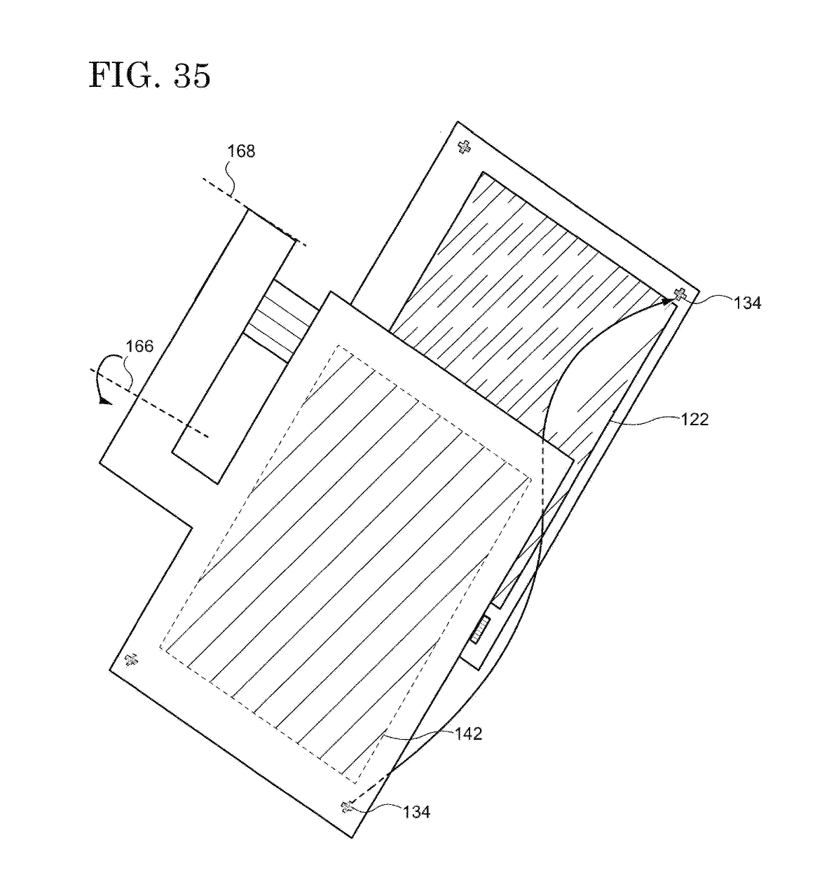

Alternatively, a display device of the present embodiment may be a display device 370 having a structure shown in FIG. 32, FIG. 33A, FIG. 33B, and FIG. 33C. FIG. 33A, FIG. 33B, and FIG. 33C are schematic cross-sectional views along chain lines J-J′, K-K′, and L-L′ of FIG. 32, respectively. The display device 370 is different from the display devices 350 and 360 in folding mode of the boundary region 160. More specifically, as shown in FIG. 34 and FIG. 35, the boundary region 160 is folded along the axis 168, the portion of the boundary region 160 further up than the axis 168 is lifted up, and the touch portion 142 is arranged so as to face the image-display portion 122. After that, the boundary region 160 is further folded along the axis 166, and the touch region 140 is arranged over the display region 120 so that the alignment markers in the touch region 140 cover the alignment markers 134 in the display region 120.

Such deformation allows production of the display device 370. Hence, as shown in FIG. 33C, a part of the boundary region 160 is positioned over the touch region 140.

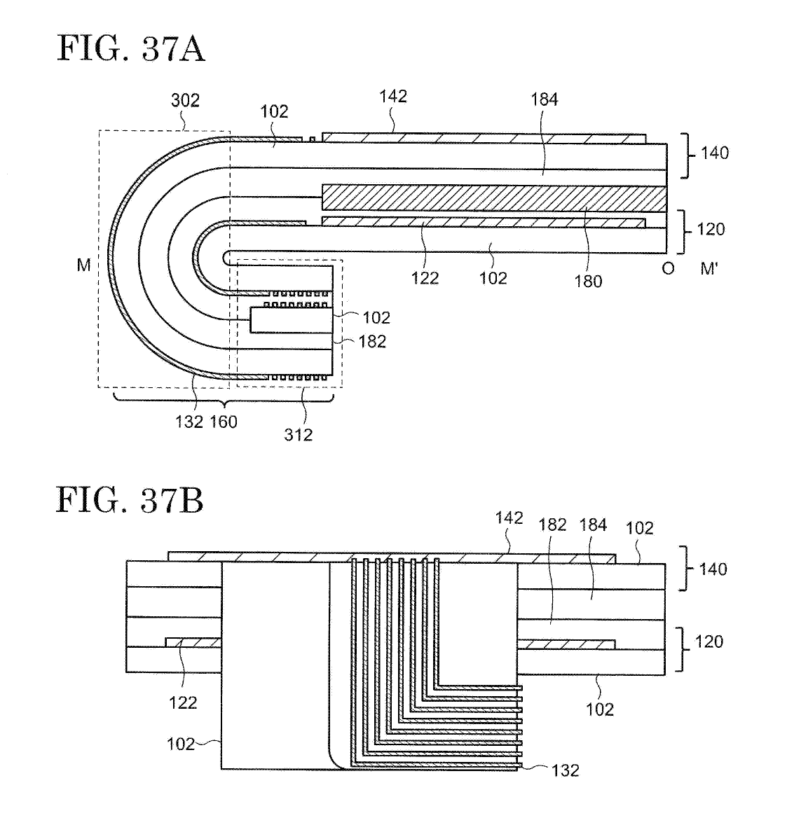

Alternatively, a display device of the present embodiment may be a display device 380 having a structure shown in FIG. 36, FIG. 37A, and FIG. 37B. FIG. 37A is a cross-sectional view along a chain line M-M′ of FIG. 36, and FIG. 37B is a side view observed from a M side of the chain line M-M′. That is, the boundary region 160 may possess an overlapping portion 312 which is positioned under the display region 120 and overlaps with the display region 120 and the touch region 140 and the protruding portion 302 protruding in a direction parallel to the first side 128 from a region in which the display region 120 and the touch region 140 overlap with each other. The protruding portion 302 connects the overlapping portion 312 to the display region 120 and the overlapping portion 312 to the touch region 140. Wirings 132 extend from the display region 120 to the touch region 140 through the protruding portion 302, the overlapping portion 312, and the protruding portion 302 in this order. Therefore, the wirings 132 extend on a side surface of the protruding portion 302 from under the display region 120 to the touch region 140 (FIG. 37B).

Such a structure can be formed by folding the protruding portion 302 of the display device 350 shown in FIG. 24 along an axis 164 and placing a part of the protruding portion 302 under the display region 120. With this structure, an area (an area of a frame) other than that of the display region 120 or the touch region 140 can be reduced.

Furthermore, another mode of a display device of the present embodiment is a display device 390 shown in FIG. 38. The display device 390 is different from the display device 350 in position of the protruding portion 302 originating from the boundary region 160. Namely, the protruding portion 302 of the display device 390 is formed on side surfaces of the display region 120 and the touch region 140 which are close to the first terminals 124 and the second terminals 126.

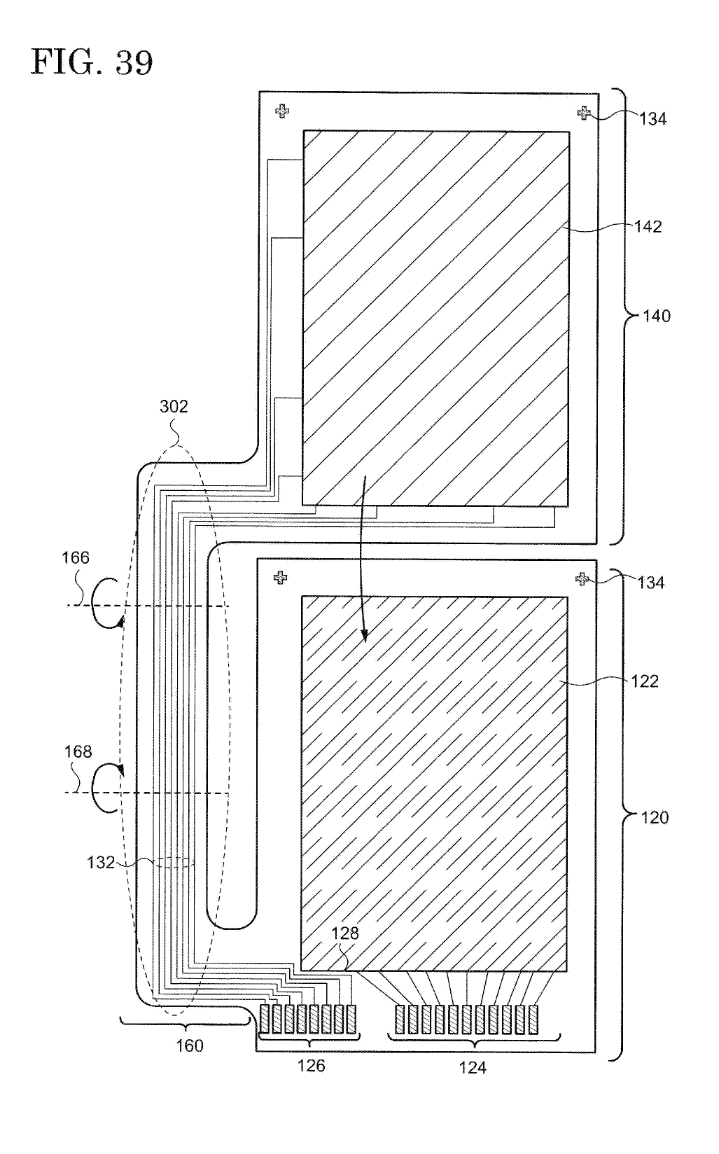

The display device 390 having such a structure can be fabricated by a method similar to that of the display device 350. A difference from the fabrication method of the display device 350 is that the boundary region 160 is formed so as to extend to the side surface of the touch region 140 close to the first terminals 124 and the second terminals 126 from the side surface of the display region 120 close to the first terminals 124 and the second terminals 126 as shown in FIG. 39. Similar to the display device 350, the display device 390 can be formed by folding the boundary region 160 along the axes 166 and 168 according to a direction of an arrow and placing the touch region 140 over the display region 120 so that the alignment markers 134 in the touch region 140 and the display region 120 overlap with each other.

In the display device 390, the wirings 132 extending from the second terminals 126 to the touch portion 142 pass through the boundary region 160 but are not arranged in the frame beside the image-display portion 122. Hence, the wirings 132 are arranged apart from the image-display portion 122 by which influence of a variety of signals supplied to the image-display portion 122 on the operation of the touch portion 142 can be suppressed.

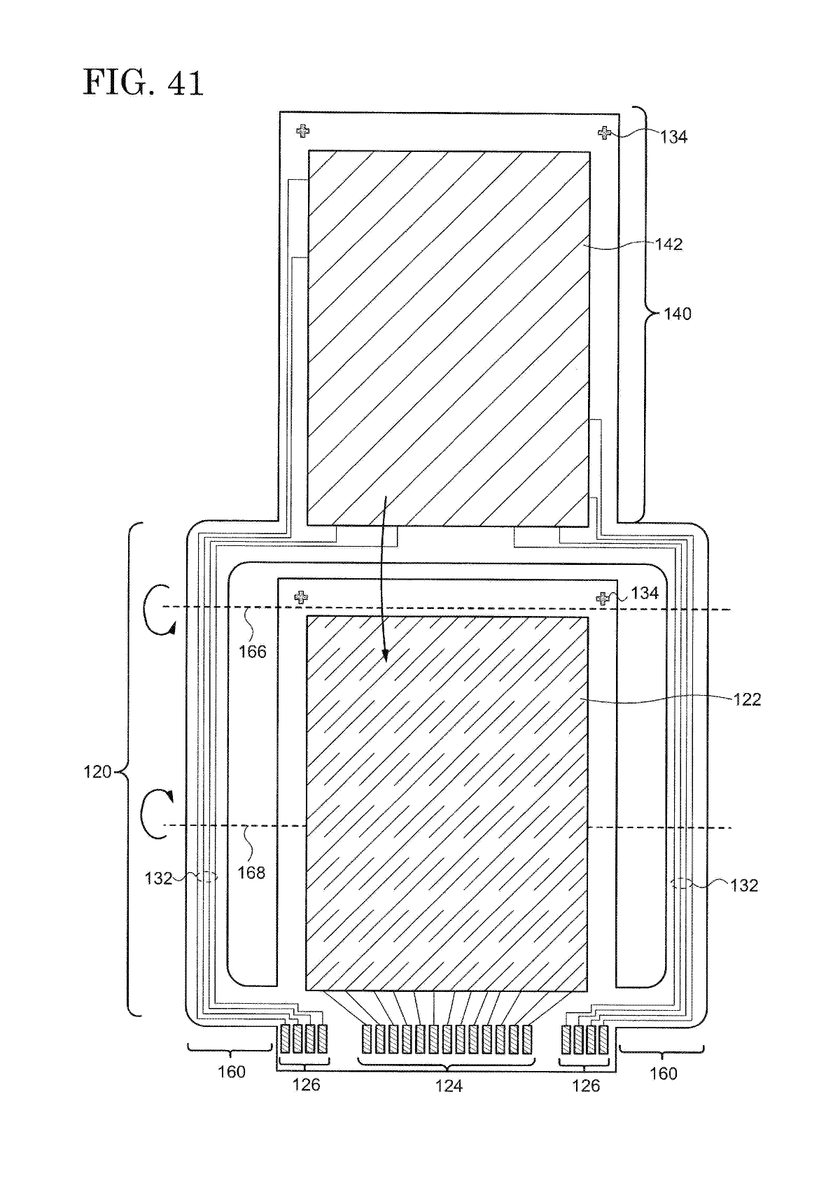

The protruding portion 302 originating from the boundary region 160 is not limited to one. For example, as demonstrated by a display device 400 shown in FIG. 40, the protruding portions 302 may be disposed on both sides of the display device so as to sandwich the image-display portion 122 and the touch portion 142. Similar to the display device 390, the display device 400 can be fabricated by folding the boundary region 160 along the axes 166 and 168 according to a direction of an arrow and placing the touch region 140 over the display region 120 so that the alignment markers 134 of the touch region 140 and the display region 120 overlap with each other as shown in FIG. 41.

In the display device 400, the wirings 132 extending from the second terminals 126 are connected to the touch portion 142 via one of the two boundary regions 160. Therefore, widths of the left and right boundary regions 160 can be reduced.

It is not always necessary to arrange the protruding portion 302 on the side surface of the display device, and the protruding portion 302 may be formed on an upper portion of the image-display portion 122 or the touch portion 142 as demonstrated by a display device 410 shown in FIG. 42. That is, the protruding portion 302 may be formed on a side surface opposing the first side 128 with the image-display portion 122 interposed therebetween. In this case, the protruding portion 302 protrudes in a direction perpendicular to the first side 128. Moreover, the protruding portion 302 may be disposed at a position shifted in a left or right direction.

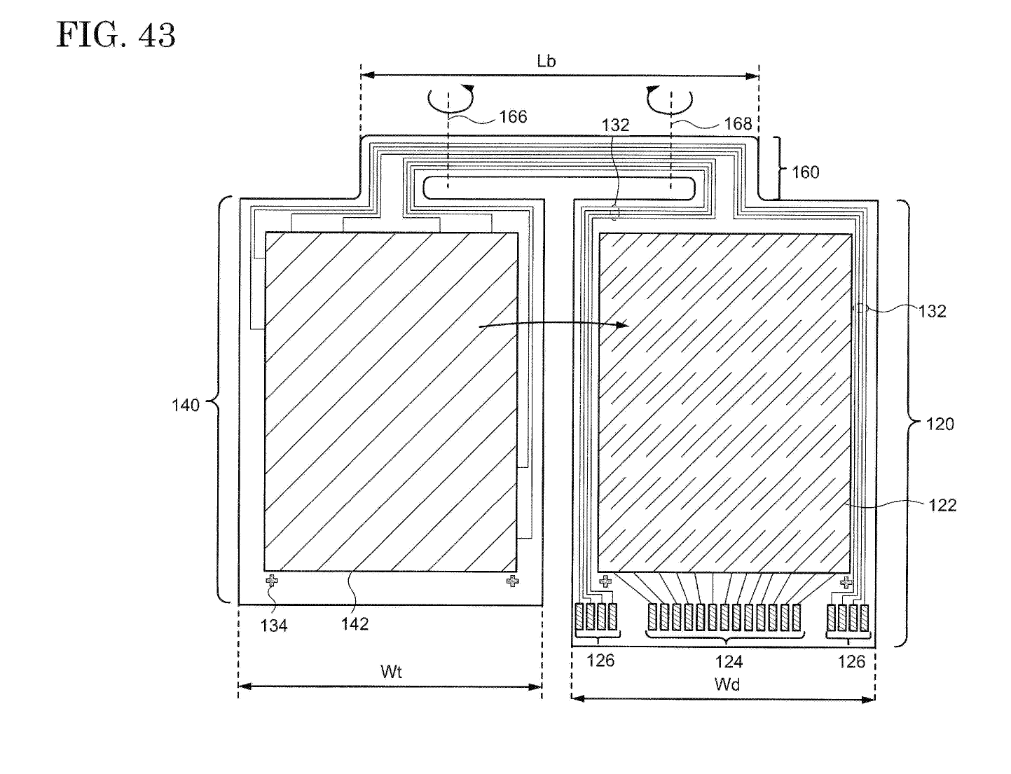

As shown in FIG. 43, the display device 410 can be fabricated by respectively arranging the display region 120 and the touch region 140 on left and right sides and folding the base film 102 having the boundary region 160 connected to upper sides thereof along the axes 166 and 168 so that the touch region 140 covers the display region 120. A length Lb of the boundary region 160 may be ½ or more of a summation of a width Wd of the display region 120 and a width Wt of the touch region 140. In FIG. 43, an example is shown in which the display region 120 is positioned on a right side with respect to the touch region 140. However, the display region 120 may be disposed on a left side with respect to the touch region 140.

As described above, the display devices 350, 360, 370, 380, 390, 400, and 410 described in this embodiment are different from the display devices 100, 270, 272, 274, and 276 in that the touch portion 142 is formed over the base film 102 in the touch region 140. That is, the touch portion 142 is arranged on a position closer to a user. Hence, it is possible to sense a touch by a user at a higher sensitivity.

### Sixth Embodiment

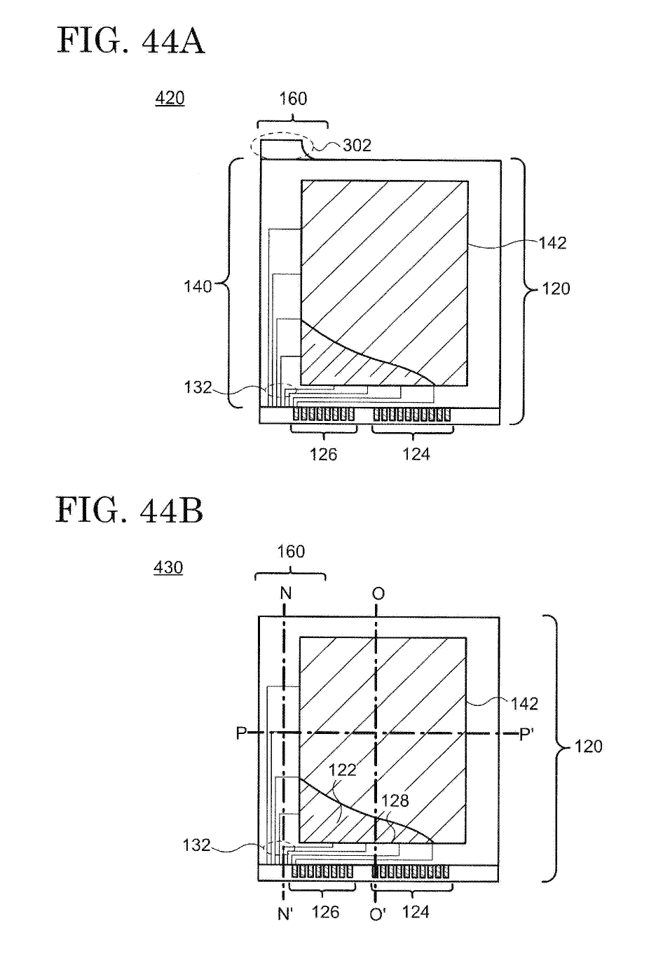

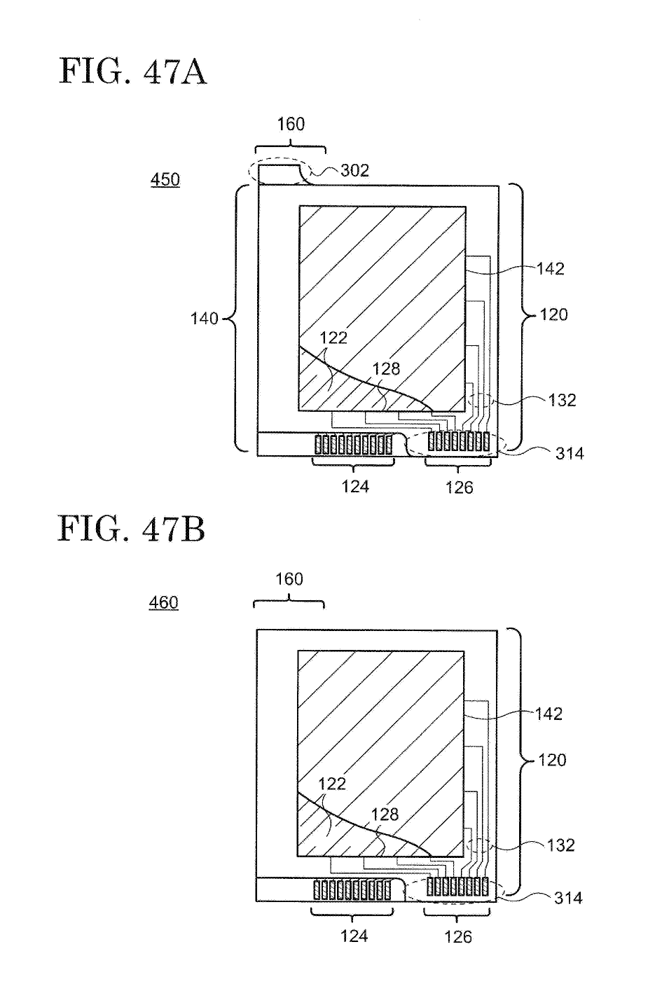

In the present embodiment, display devices with a structure different from those of the display devices described in the First, and Third to Fifth Embodiments are explained by using FIG. 44A to FIG. 50. The structures which are the same as those of the First to Fifth Embodiments may be omitted. Note that the base film 102 of the touch region 140 provided over the display region 120 is not illustrated in FIG. 44A, FIG. 44B, FIG. 47A, and FIG. 47B for clarity.

Top views of display devices 420 and 430 of the present embodiment are shown in FIG. 44A and FIG. 44B, respectively. The display device 420 and 430 are different from the display devices described in the First and Third to Fifth Embodiments in that a part of or the entire boundary portion 160 exists in a region in which the display region 120 overlaps with the touch region 140. In the display device 420, a part of the boundary region 160 exists in the region where the display region 120 overlaps with the touch region 140, and another part thereof sticks out of this region to form the protruding portion 302. On the other hand, in the display device 430, the entire boundary region 160 exists in the region where the display region 120 overlaps with the touch region 140.

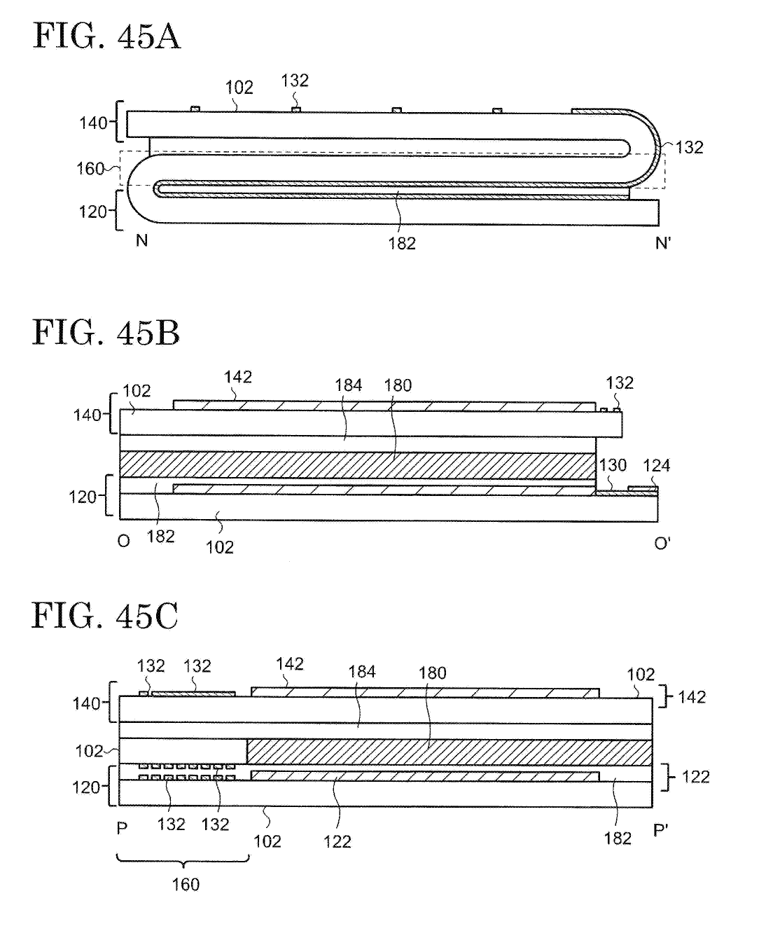

Schematic views of cross-sections along chain lines N-N′, O-O′, and P-P′ in FIG. 44B are shown in FIG. 45A, FIG. 45B, and FIG. 45C, respectively. As shown in FIG. 45A and FIG. 45C, the base film 102 has a three-folded structure, and the boundary region 160 exists in the region where the display region 120 overlaps with the touch region 140. As shown in FIG. 45B, the touch portion 142 is formed over the base film 102 in the touch region 140. Hence, the transparent substrate 180 is not in contact with the touch portion 142 but adhered to the base film 102 of the touch region 140 through the adhesion layer 184. In such a structure, the touch portion 142 is arranged at a position closer to a user. Hence, it is possible to sense a touch by a user at a higher sensitivity.

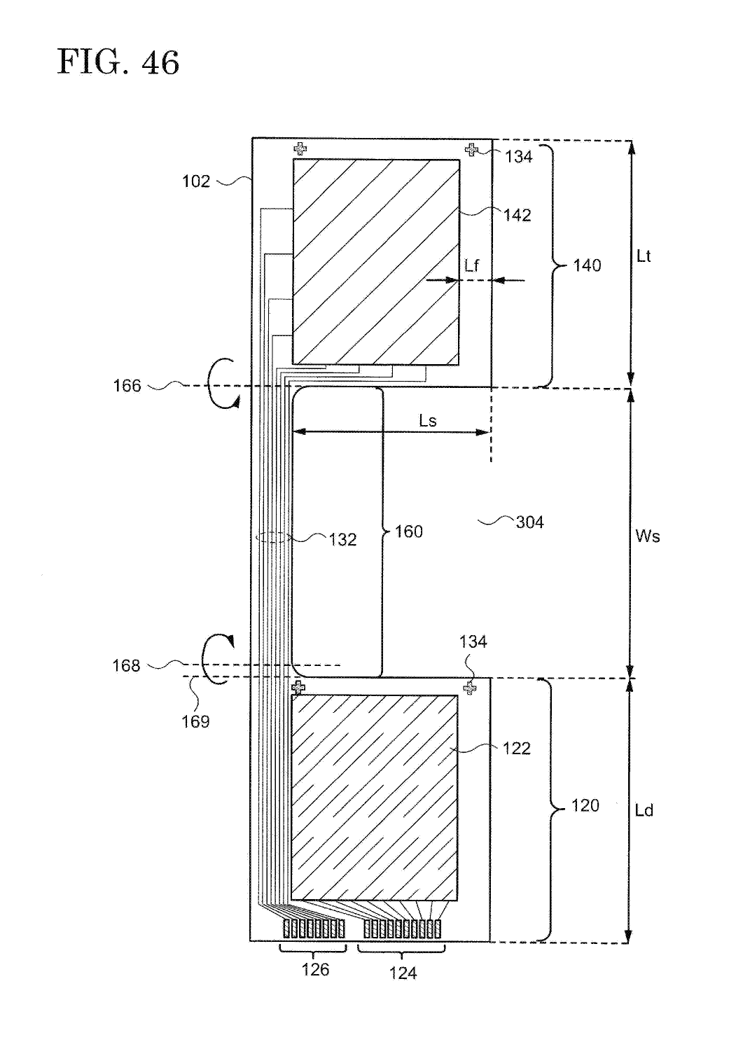

The display device 430 can be fabricated by a method shown in FIG. 46. That is, the slit 304 in contact with the display region 120 and the touch region 140 is provided to the base film 102 in the boundary region 160 between the display region 120 and the touch region 140. A length Ls of the slit 304 may be equal to or longer than a summation of a width of the touch portion 142 or the image-display portion 122 and a width Lf of the frame. Therefore, a width of the boundary region 160 is equal to or smaller than that of the frame. A width Ws of the slit 304 may be at least equal to or larger than a length Lt of the touch region 140. After that, the boundary region 160 is folded along the axis 166 and an axis 169 overlapping with a side of the display region 120 so that the touch region 140 is positioned over the display region 120, the front surface of the touch portion 142 overlaps with the image-display portion 122 with the touch portion 142 sandwiched therebetween, and the alignment markers 134 in the touch region 140 match the alignment markers 134 in the display region 120, thereby giving the display device 430. Note that the display device 420 can be obtained when the display region 160 is folded along the axis 168 which is closer to the touch portion 142 than the axis 169.

In the display devices 420 and 430, the first terminals 124 and the second terminals 126 are each formed over the base film 102 in the display region 120. However, the present embodiment is not limited to such a structure. For example, as demonstrated by display devices 450 and 460 shown in FIG. 47A and FIG. 47B, the first terminals 124 may be formed over the base film 102 in the display region 120, while the second terminals 126 may be formed over the base film 102 in the touch region 140. Additionally, the wirings 132 are provided over the base film 102 in the touch region 140. In this case, it is preferred that a tab 314 be provided to the base film 102 in the touch region 140 and the second terminals 126 be formed thereover. This structure allows both first terminals 124 and second terminals 126 to be arranged at a vicinity of the first side 128 and the first terminals 124 to be exposed from the base film 102 of the touch region 140.

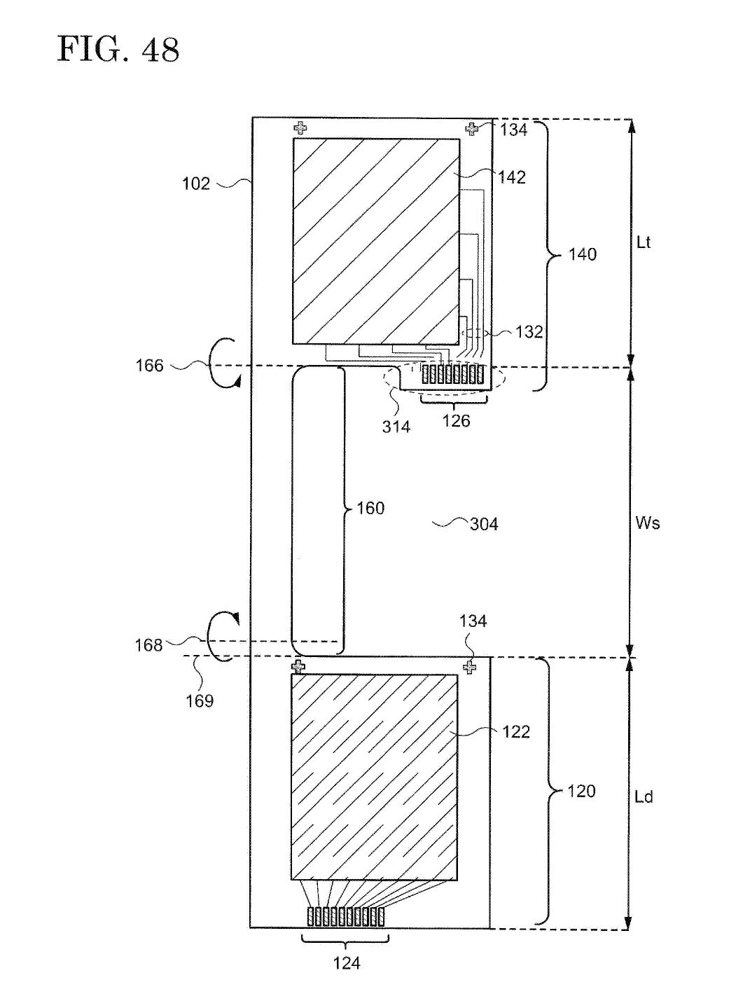

Similar to the display devices 420 and 430, the display devices 450 and 460 can be fabricated with a method shown in FIG. 48. The display device 460 is obtained by folding along the axes 166 and 169, whereas the display device 450 is obtained by folding along the axes 166 and 168.

As shown FIG. 48, it is not necessary to arrange the wirings 132 in the boundary region 160 in the display device 450 and 460. Hence, a width of the boundary region 160 can be reduced. As a result, a width of the frame can be decreased.

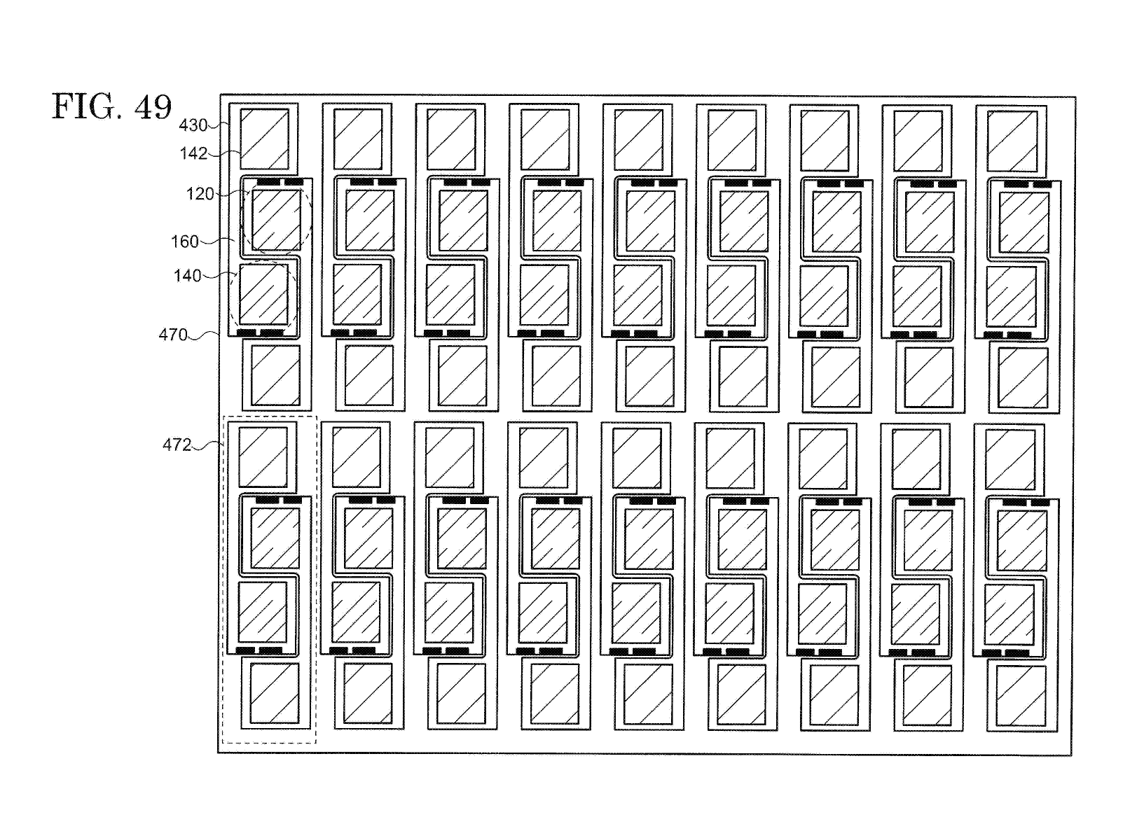

When the display device 420, 430, 450, or 460 is mass-produced, a plurality of display devices is fabricated over a large-size mother glass and separated from each other. For example, an arrangement example in the case where the display devices 430 are mass-produced is shown in FIG. 49. As shown in FIG. 49, the display devices 430 which are in the developed state prior to folding the boundary region 160 are regularly arranged. In this case, one of a pair of the display devices 430 may be placed upside down, and the display region 120 thereof is inserted to the slit 304 (see FIG. 46) of the other display devices 430 to form a substantially rectangular region 472. Arrangement of the rectangular regions 472 on the mother glass 470 enables the display devices 430 in the developed state to be more densely arranged since the mother glass 470 is normally rectangular. Hence, manufacturing cost of the display device 430 can be decreased.

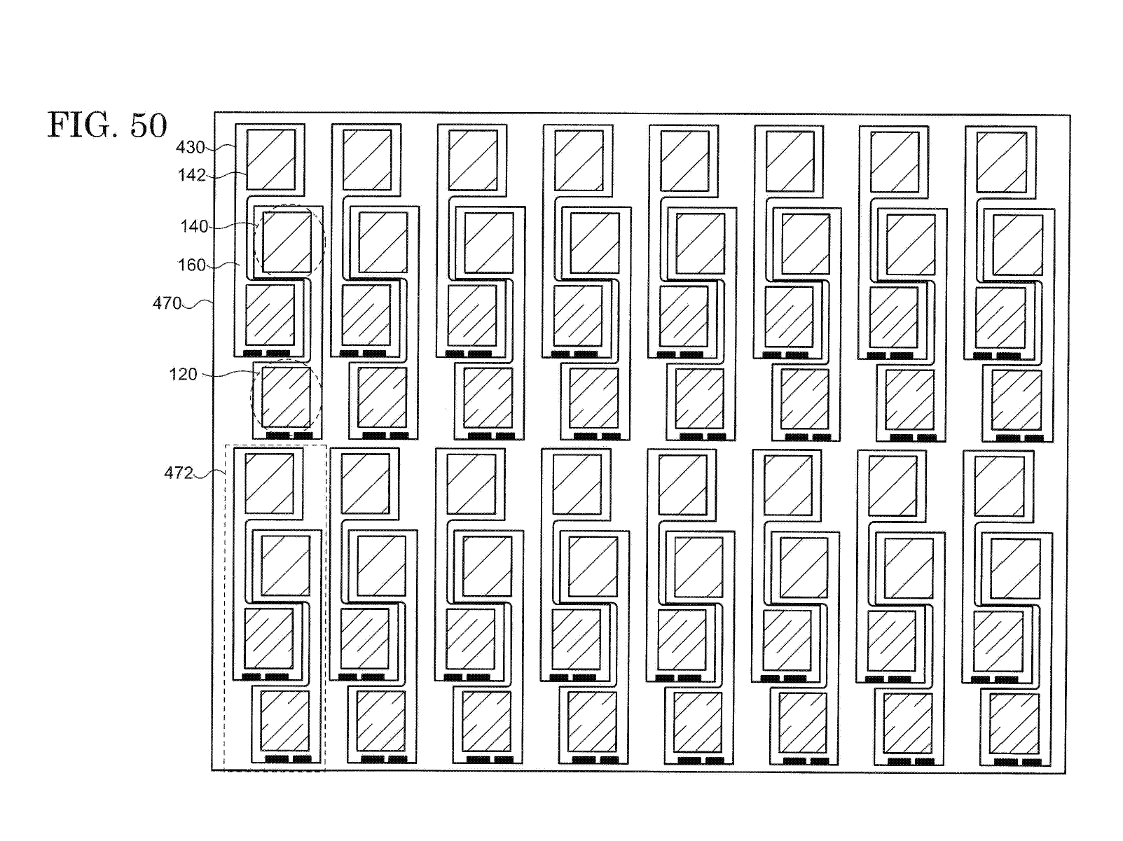

Alternatively, the rectangular region 472 may be formed by combining two display devices 430 with symmetric structures. In FIG. 50, the touch region 140 of one of two display devices 430 is inserted to the slit 304 of the other display device 430.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process is included in the scope of the present invention as long as they possess the concept of the present invention.

In the specification, although the cases of the organic EL display device are exemplified, the embodiments can be applied to any kind of display devices of the flat panel type such as other self-emission type display devices, liquid crystal display devices, and electronic paper type display device having electrophoretic elements and the like. In addition, it is apparent that the size of the display device is not limited, and the embodiment can be applied to display devices having any size from medium to large.

It is properly understood that another effect different from that provided by the modes of the aforementioned embodiments is achieved by the present invention if the effect is obvious from the description in the specification or readily conceived by persons ordinarily skilled in the art.

What is claimed is:

1. A display device comprising:
a base film including:
a display region comprising an image-display portion which has a transistor including a gate electrode and a source/drain electrode;
a touch region comprising a touch portion which has a plurality of electrodes electrically connected to each other with a connection electrode; and
a boundary region between the display region and the touch region,
wherein:
the connection electrode exists in the same layer as one of the gate electrode and the source/drain electrode;
the base film is folded in the boundary region so that a back surface of the touch portion opposes the image-display portion with the touch portion sandwiched therebetween;
the image-display portion and the touch portion are sandwiched by the base film; and
the back surface of the touch portion is one of two surfaces of the touch portion opposing each other, which is closer to the base film.

2. The display device according to claim 1, further comprising:
a transparent substrate between the image-display portion and the touch portion,
wherein the transparent substrate is adhered to the image-display portion and the touch portion.

3. The display device according to claim 1,
wherein the display region further comprises:
a plurality of first terminals over the base film, the plurality of first terminals being electrically connected to the image-display portion; and
a plurality of second terminals over the base film, the plurality of second terminals being electrically connected to the touch portion.

4. The display device according to claim 3, further comprising:
wirings electrically connecting the plurality of second terminals to the touch portion,
wherein the wirings extend to the touch region from the display region through the boundary region.

5. The display device according to claim 1,
wherein the boundary region protrudes from a region in which the image-display portion and the touch portion overlap with each other.

6. The display device according to claim 5,
wherein a width of the boundary region in a direction of a folding axis is smaller than a width of the display region and a width of the touch region.

7. A display device comprising:
a base film including a display region, a touch region, and a boundary region between the display region and the touch region;
an image-display portion over the display region; and
a touch portion over the touch region,
wherein:
the base film is folded in the boundary region so that a front surface of the touch portion overlaps with the image-display portion with the touch portion sandwiched therebetween;
the boundary region protrudes from a region in which the image-display portion and the touch portion overlap with each other;
the protruding portion of the base film has a three-folded structure; and
the front surface of the touch portion is one of two surfaces of the touch portion opposing each other, which is farther from the base film.

8. The display device according to claim 7, further comprising:
a transparent substrate between the image-display portion and the touch portion,
wherein the transparent substrate is adhered to the image-display portion and the base film in the touch region.

9. The display device according to claim 7,
wherein:
the image-display portion comprises a transistor including a gate electrode and a source/drain electrode;
the touch portion comprises a plurality of electrodes electrically connected to each other with a connection electrode; and
the connection electrode exists in the same layer as one of the gate electrode and the source/drain electrode.

10. The display device according to claim 7,
wherein the display region further comprises:
a plurality of first terminals over the base film, the plurality of first terminals being electrically connected to the image-display portion; and
a plurality of second terminals over the base film, the plurality of second terminals being electrically connected to the touch portion.

11. The display device according to claim 10, further comprising:
a wiring electrically connecting one of the plurality of second terminals to the touch portion,
wherein the wiring extends to the touch region from the display region through the boundary region.

12. The display device according to claim 10,
wherein:
the plurality of first terminals and the plurality of second terminals are each arranged parallel to a first side of the image-display portion; and
the protruding portion protrudes in a direction perpendicular to the first side from a region in which the image-display portion overlaps with the touch portion.

13. The display device according to claim 10,
wherein:
the plurality of first terminals and the plurality of second terminals are each arranged parallel to a first side of the image-display portion; and
the protruding portion protrudes in a direction parallel to the first side from a region in which the image-display portion overlaps with the touch portion.

14. A display device comprising:
a base film including a display region, a touch region, and a boundary region between the display region and the touch region;
an image-display portion over the display region; and
a touch portion over the touch region,
wherein:
the base film is folded in the boundary region so that a front surface of the touch portion overlaps with the image-display portion with the touch portion sandwiched therebetween;
the base film in the boundary region has a three-folded structure and is sandwiched between the display region and the touch region; and
the front surface of the touch portion is one of two surfaces of the touch portion opposing each other, which is farther from the base film.

15. The display device according to claim 14, further comprising:
a transparent substrate between the image-display portion and the touch portion,
wherein the transparent substrate is adhered to the image-display portion and the base film in the touch region.

16. The display device according to claim 14,
wherein:
the image-display portion comprises a transistor including a gate electrode and a source/drain electrode;
the touch portion comprises a plurality of electrodes electrically connected to each other with a connection electrode; and
the connection electrode exists in the same layer as one of the gate electrode and the source/drain electrode.

17. The display device according to claim 14,
wherein the display region further comprises:
a plurality of first terminals over the base film, the plurality of first terminals being electrically connected to the image-display portion; and
a plurality of second terminals over the base film, the plurality of second terminals being electrically connected to the touch portion.

18. The display device according to claim 17, further comprising:
wirings electrically connecting the plurality of second terminals to the touch portion,
wherein the wirings extend to the touch region from the display region through the boundary region.

19. The display device according to claim 14,
wherein:
the display region further comprises a plurality of first terminals over the base film, the plurality of first terminals being electrically connected to the image-display portion; and
the touch region further comprises a plurality of second terminals over the base film, the plurality of second terminals being electrically connected to the touch portion.
